(19) United States
(12) Patent Application Publication
(10) Pub. No.: US 2025/0318366 A1
(43) Pub. Date: Oct. 9, 2025

(54) DISPLAY DEVICE AND ELECTRONIC DEVICE INCLUDING THE SAME

(71) Applicant: Samsung Display Co., LTD., Yongin-si (KR)

(72) Inventors: Hyewon Kim, Yongin-si (KR); YOOMIN KO, Yongin-si (KR); SUNHO KIM, Yongin-si (KR); JUCHAN PARK, Yongin-si (KR); Yerim Son, Yongin-si (KR); PILSUK LEE, Yongin-si (KR); CHUNG SOCK CHOI, Yongin-si (KR); SUNGJIN HONG, Yongin-si (KR)

(73) Assignee: Samsung Display Co., LTD., Yongin-si (KR)

(21) Appl. No.: 19/091,214

(22) Filed: Mar. 26, 2025

(30) Foreign Application Priority Data
Apr. 3, 2024 (KR) 10-2024-0045217

(51) Int. Cl. H10K 59/122

(52) U.S. Cl. CPC H10K 59/122

(57) ABSTRACT

A display device includes a first pixel driving circuit and a second pixel driving circuit, a first connection electrode connected to the first pixel driving circuit, a second connection electrode connected to the second pixel driving circuit, a first electrode disposed on the first connection electrode and the second connection electrode, a pixel defining layer covering at least a portion of the first electrode and defining a first emission area and a second emission area, a first connection pattern connected to the first connection electrode and partially surrounding the first emission area, a second connection pattern connected to the second connection electrode and partially surrounding the second emission area, a separator covering at least a portion of each of the first connection pattern and the second connection pattern, and an electrode layer connected to each of the first connection pattern and the second connection pattern.

### CROSS-REFERENCE TO RELATED APPLICATION(S)

This application claims priority to and benefits of Korean Patent Application No. 10-2024-0045217 under 35 U.S.C. § 119, filed on Apr. 3, 2024, in the Korean Intellectual Property Office (KIPO), the entire contents of which are incorporated herein by reference.

### BACKGROUND

### 1. Technical Field

Embodiments relate to a display device that provides visual information and an electronic device including the display device.

### 2. Description of the Related Art

As information technology develops, the importance of a display device, which is a connection medium between a user and information, has been emphasized. The display device includes light emitting elements and pixel driving circuits for driving the light emitting elements. The light emitting elements are driven by the pixel driving circuits to emit light. In order to improve a reliability of the display device, studies on connections between the light emitting elements and the pixel driving circuits are being conducted.

### SUMMARY

Embodiments provide a display device with improved display characteristics.

Embodiments also provide an electronic device including the display device.

Additional features of the disclosure will be set forth in the description which follows, and in part will be apparent from the description, or may be learned by practice of the disclosure.

A display device according to an embodiment may include a first pixel driving circuit and a second pixel driving circuit each including a transistor, a first connection electrode electrically connected to the first pixel driving circuit, a second connection electrode electrically connected to the second pixel driving circuit, a first electrode disposed on the first connection electrode and the second connection electrode, a pixel defining layer covering at least a portion of the first electrode and defining a first emission area and a second emission area adjacent to each other, a first connection pattern electrically connected to the first connection electrode and partially surrounding the first emission area in a plan view, a second connection pattern electrically connected to the second connection electrode and partially surrounding the second emission area in the plan view, a separator disposed on the pixel defining layer, the first connection pattern, and the second connection pattern and covering at least a portion of each of the first connection pattern and the second connection pattern, and an electrode layer disposed on the first electrode and electrically connected to each of the first connection pattern and the second connection pattern.

In an embodiment, in the plan view, one of the first connection pattern and the second connection pattern may be disposed between the first emission area and the second emission area.

In an embodiment, a cross-sectional shape of a portion of the separator may be asymmetrical.

In an embodiment, a side surface of the portion of the separator may contact one of the first connection pattern and the second connection pattern. Another side surface, which is opposite to the side surface, of the portion of the separator may contact the pixel defining layer and may not contact the first connection pattern nor the second connection pattern.

In an embodiment, the first connection pattern and the second connection pattern may be electrically insulated from each other.

In an embodiment, the separator may define a first open area exposing a portion of the first connection pattern and a second open area exposing a portion of the second connection pattern in the plan view. The electrode layer may be separated into an electrode disposed in the first open area and another electrode disposed in the second open area by the separator.

In an embodiment, the electrode disposed in the first open area may contact the first connection pattern at a position adjacent to or overlapping the separator in the plan view. The another electrode disposed in the second open area may contact the second connection pattern at another position adjacent to or overlapping the separator in the plan view.

In an embodiment, the electrode disposed in the first open area may be electrically connected to the first pixel driving circuit through the first connection electrode and the first connection pattern. The another electrode disposed in the second open area may be electrically connected to the second pixel driving circuit through the second connection electrode and the second connection pattern.

In an embodiment, the electrode disposed in the first open area and the another electrode disposed in the second open area may be electrically insulated from each other.

In an embodiment, the electrode layer may include a first sub-electrode layer including a first conductive material, and a second sub-electrode layer disposed on the first sub-electrode layer and including a second conductive material. The first conductive material and the second conductive material may be different from each other.

In an embodiment, the first conductive material may be a metal, and the second conductive material may be a transparent conductive oxide.

In an embodiment, the first sub-electrode layer may contact each of the first connection pattern and the second connection pattern at a position adjacent to or overlapping the separator in the plan view. The second sub-electrode layer may contact each of the first connection pattern and the second connection pattern at the position adjacent to or overlapping the separator in the plan view.

In an embodiment, in the plan view, a size of an area where the second sub-electrode layer overlaps the first connection pattern may be greater than a size of an area where the first sub-electrode layer overlaps the first connection pattern. In the plan view, a size of an area where the second sub-electrode layer overlaps the second connection pattern may be greater than a size of an area where the first sub-electrode layer overlaps the second connection pattern.

In an embodiment, the separator may include a groove in which a portion of an upper surface of the separator is recessed.

In an embodiment, the display device may further include a dummy layer disposed in the groove, the dummy layer and the electrode layer including a same material. The electrode layer may extend along a side surface of the separator to the upper surface of the separator. The electrode layer and the dummy layer may be separated from each other by the groove.

In an embodiment, the display device may further include an intermediate layer disposed between the first electrode and the electrode layer and including an emission material.

A display device according to an embodiment may include a pixel driving circuit including a transistor, a connection electrode electrically connected to the pixel driving circuit, a first electrode disposed on the connection electrode, a pixel defining layer covering at least a portion of the first electrode and defining an emission area, a connection pattern electrically connected to the connection electrode and partially surrounding the emission area in a plan view, a separator disposed on the pixel defining layer and the connection pattern and covering at least a portion of the connection pattern, and a second electrode disposed on the first electrode and electrically connected to the connection pattern.

In an embodiment, a cross-sectional shape of a portion of the separator may be asymmetrical.

In an embodiment, a side surface of the portion of the separator may contact the connection pattern. Another side surface, which is opposite to the side surface, of the portion of the separator may contact the pixel defining layer and may not contact the connection pattern.

In an embodiment, the separator may define an open area exposing a portion of the connection pattern in the plan view. The second electrode may be disposed in the open area, may contact the connection pattern at a position adjacent to or overlapping the separator in the plan view, and may be electrically connected to the pixel driving circuit through the connection electrode and the connection pattern.

In an embodiment, the display device may further include an intermediate layer disposed between the first electrode and the second electrode and including an emission material.

A display device according to an embodiment may include a pixel driving circuit including a transistor, a connection electrode electrically connected to the pixel driving circuit, an insulating layer defining a first sub-opening exposing at least a portion of the connection electrode in a plan view, a first electrode disposed on the insulating layer, a pixel defining layer covering at least a portion of the first electrode, defining an emission area, and defining a second sub-opening overlapping the first sub-opening in the plan view, a connection pattern electrically connected to the connection electrode and surrounding the emission area in the plan view, a separator disposed on the pixel defining layer and the connection pattern, covering at least a portion of the connection pattern, and overlapping the first sub-opening and the second sub-opening in the plan view, and a second electrode disposed on the first electrode and electrically connected to the connection pattern.

In an embodiment, the connection pattern may partially surround the emission area in the plan view. A cross-sectional shape of a portion of the separator may be asymmetric.

In an embodiment, a side surface of the portion of the separator may contact the connection pattern. Another side surface, which is opposite to the side surface, of the portion of the separator may contact the pixel defining layer and may not contact the connection pattern.

In an embodiment, the first sub-opening and the second sub-opening may be connected to form an opening that penetrates the pixel defining layer and the insulating layer and exposes a portion of the connection electrode in the plan view. The opening may overlap the separator in the plan view.

In an embodiment, the connection pattern may be electrically connected to the connection electrode through the opening.

In an embodiment, the separator may define an open area exposing a portion of the connection pattern in the plan view. The second electrode may be disposed in the open area, may contact the connection pattern at a position adjacent to or overlapping the separator in the plan view, and may be electrically connected to the pixel driving circuit through the connection electrode and the connection pattern.

In an embodiment, the display device may further include an intermediate layer disposed between the first electrode and the second electrode and including an emission material.

An electronic device according to an embodiment may include a display device and a power supply configured to provide power to the display device. The display device may include a first pixel driving circuit and a second pixel driving circuit each including a transistor, a first connection electrode electrically connected to the first pixel driving circuit, a second connection electrode electrically connected to the second pixel driving circuit, a first electrode disposed on the first connection electrode and the second connection electrode, a pixel defining layer covering at least a portion of the first electrode and defining a first emission area and a second emission area adjacent to each other, a first connection pattern electrically connected to the first connection electrode and partially surrounding the first emission area in a plan view, a second connection pattern electrically connected to the second connection electrode and partially surrounding the second emission area in the plan view, a separator disposed on the pixel defining layer, the first connection pattern, and the second connection pattern and covering at least a portion of each of the first connection pattern and the second connection pattern, and an electrode layer disposed on the first electrode and electrically connected to each of the first connection pattern and the second connection pattern.

The display device according to embodiments may include the connection electrode, the connection pattern, and the separator. Accordingly, a cathode disposed on an anode may be readily connected to the pixel driving circuit. For example, the cathode disposed on the anode may be connected to a drain of a driving transistor of the pixel driving circuit through the connection electrode and the connection pattern. Accordingly, even in case that a light emitting element deteriorates, a gate-source voltage (Vgs) of the driving transistor may not change. Accordingly, a range of change in a driving current due to the deterioration of the light emitting element may be reduced. Therefore, an after-image defect of the display device due to an increase in the time of use may be reduced, and a lifespan of the display device may be improved.

According to embodiments, in a plan view, the connection pattern may partially surround the emission area. Accordingly, a limitation of the design of the emission area due to the connection pattern may be reduced. Accordingly, a degree of design freedom of the emission area may be improved, and a size of the emission area (i.e., an aperture ratio) may be increased. Therefore, display characteristics of the display device may be improved.

It is to be understood that both the foregoing general description and the following detailed description are exemplary and explanatory and are intended to provide further explanation of the disclosure as claimed.

### BRIEF DESCRIPTION OF THE DRAWINGS

The accompanying drawings, which are included to provide a further understanding of the disclosure and are incorporated in and constitute a part of this specification, illustrate embodiments of the disclosure, and together with the description serve to explain the disclosure.

FIG. 1A is a plan view illustrating a display device according to an embodiment.

FIG. 1B is a plan view illustrating a display device according to an embodiment.

FIG. 2A is a schematic diagram of an equivalent circuit illustrating a circuit structure of a pixel included in the display device of FIGS. 1A and 1B according to an embodiment.

FIG. 2B is a schematic diagram of an equivalent circuit illustrating a circuit structure of a pixel included in the display device of FIGS. 1A and 1B according to an embodiment.

FIG. 2C is a schematic diagram of an equivalent circuit illustrating a circuit structure of a pixel included in the display device of FIGS. 1A and 1B according to an embodiment.

FIGS. 3 and 4 are plan views schematically illustrating a portion of the display device of FIGS. 1A and 1B according to an embodiment.

FIG. 5 is an enlarged view illustrating one of unit emission areas of FIG. 4 according to an embodiment.

FIG. 6 is a schematic cross-sectional view taken along line I-I′ of FIG. 5 according to an embodiment.

FIG. 7 is a schematic cross-sectional view taken along line I-I′ of FIG. 5 according to an embodiment.

FIG. 8 is an enlarged view illustrating one of unit emission areas of FIG. 4 according to an embodiment.

FIG. 9 is a schematic cross-sectional view taken along line II-II′ of FIG. 8 according to an embodiment.

FIGS. 10 and 11 are plan views schematically illustrating a portion of the display device of FIGS. 1A and 1B according to an embodiment.

FIGS. 12 and 13 are plan views schematically illustrating a portion of the display device of FIGS. 1A and 1B according to an embodiment.

FIGS. 14 and 15 are plan views schematically illustrating a portion of the display device of FIGS. 1A and 1B according to an embodiment.

FIG. 16 is a block diagram illustrating an electronic device according to an embodiment.

### DETAILED DESCRIPTION OF THE EMBODIMENTS

Various embodiments will be described more fully hereinafter with reference to the accompanying drawings, in which some embodiments are shown. The disclosure may, however, be embodied in many different forms and should not be construed as limited to the embodiments set forth herein. Rather, these embodiments are provided so that this disclosure will be more thorough and complete, and will fully convey the scope of the disclosure to those skilled in the art. In the drawings, the sizes and relative sizes of layers and regions may be exaggerated for clarity.

In the disclosure, various modifications can be made, various forms can be used, and specific embodiments will be illustrated in the drawings and described in detail in the text. However, this is not intended to limit the disclosure to a specific form disclosed, and it will be understood that all changes, equivalents, or substitutes which fall in the spirit and technical scope of the disclosure should be included.

Although the terms “first,” “second,” etc. may be used herein to describe various types of elements, these elements should not be limited by these terms. These terms are used to distinguish one element from another element. Thus, a first element discussed below could be termed a second element without departing from the teachings of the disclosure.

When an element, such as a layer, is referred to as being “on,” “connected to,” or “coupled to” another element or layer, it may be directly on, connected to, or coupled to the other element or layer or intervening elements or layers may be present. When, however, an element or layer is referred to as being “directly on,” “directly connected to,” or “directly coupled to” another element or layer, there are no intervening elements or layers present. To this end, the term “connected” may refer to physical, electrical, and/or fluid connection, with or without intervening elements. Also, when an element is referred to as being “in contact” or “contacted” or the like to another element, the element may be in “electrical contact” or in “physical contact” with another element; or in “indirect contact” or in “direct contact” with another element.

The terminology used herein is for the purpose of describing embodiments only and is not intended to be limiting of the disclosure. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Spatially relative terms, such as “beneath,” “below,” “under,” “lower,” “above,” “upper,” “over,” “higher,” “side” (e.g., as in “sidewall”), and the like, may be used herein for descriptive purposes, and, thereby, to describe one elements relationship to another element(s) as illustrated in the drawings. Spatially relative terms are intended to encompass different orientations of an apparatus in use, operation, and/or manufacture in addition to the orientation depicted in the drawings. For example, if the apparatus in the drawings is turned over, elements described as “below” or “beneath” other elements or features would then be oriented “above” the other elements or features. Thus, the exemplary term “below” can encompass both an orientation of above and below. Furthermore, the apparatus may be otherwise oriented (e.g., rotated 90 degrees or at other orientations), and, as such, the spatially relative descriptors used herein interpreted accordingly.

In the specification and the claims, the phrase “at least one of” is intended to include the meaning of “at least one selected from the group of” for the purpose of its meaning and interpretation. For example, “at least one of A and B” may be understood to mean “A, B, or A and B.” In the specification and the claims, the term “and/or” is intended to include any combination of the terms “and” and “or” for the purpose of its meaning and interpretation. For example, “A and/or B” may be understood to mean “A, B, or A and B.” The terms “and” and “or” may be used in the conjunctive or disjunctive sense and may be understood to be equivalent to “and/or.”

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

Hereinafter, embodiments will be described in detail with reference to the accompanying drawings. The same reference numerals are used for the same components in the drawings, and redundant descriptions of the same components will be omitted.

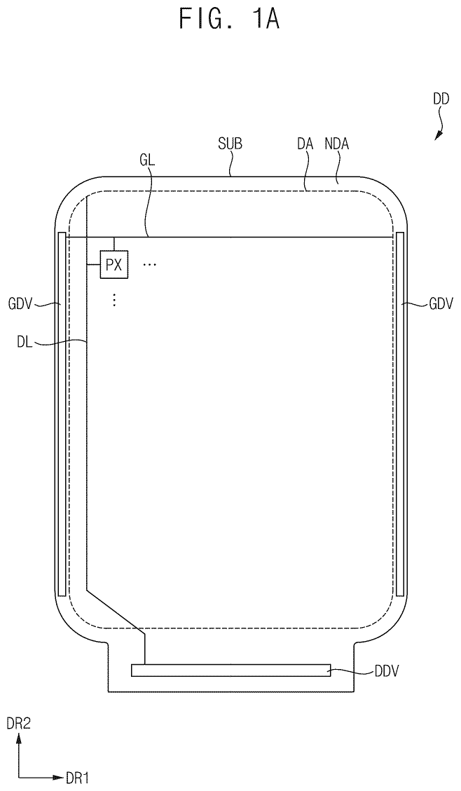

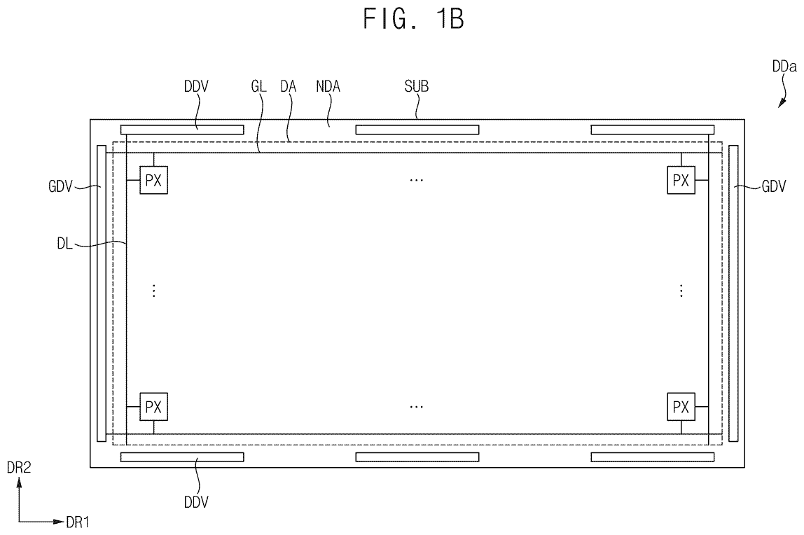

FIG. 1A is a plan view illustrating a display device according to an embodiment. FIG. 1B is a plan view illustrating a display device according to an embodiment.

Referring to FIGS. 1A and 1B, a display device DD (or DDa) may be a device activated according to an electrical signal. For example, the display device DD may be a small-sized display device used in a small-sized electronic device such as a smart phone, a mobile phone, a smart watch, a game console, a camera, or the like. For example, the display device DDa may be a medium and large-sized display device used in medium and large-sized electronic devices such as a notebook computer, a tablet PC, a television, a computer monitor, a vehicle monitor, an external billboard, or the like. FIG. 1A illustrates the display device DD as an embodiment of the small-sized display device, and FIG. 1B illustrates the display device DDa as an embodiment of the medium and large-sized display device.

The display device DD (or DDa) may include a display area DA and a peripheral area NDA. The display area DA may be an area that displays an image by generating light or controlling a transmittance of light provided from an external light source. The peripheral area NDA may be located adjacent to the display area DA. For example, the peripheral area NDA may surround at least a portion of the display area DA in a plan view. In an embodiment, the peripheral area NDA may be an area that does not display an image. However, the disclosure is not limited thereto, and an image may be displayed in at least a portion of the peripheral area NDA. For example, a light emitting element that emits light may be disposed in at least a portion of the peripheral area NDA.

The display device DD (or DDa) may include a substrate SUB, pixels PX, gate lines GL, data lines DL, a data driver DDV, and a gate driver GDV.

The substrate SUB may serve as a base of the display device DD (or DDa). In an embodiment, the substrate SUB may include glass, quartz, silicon, polymers, or the like. These may be used alone or in combination with each other. The substrate SUB may have a single-layer structure or a multi-layer structure in which multiple layers including different materials are stacked each other.

The pixels PX may be disposed in the display area DA on the substrate SUB. The pixels PX may be electrically connected to the gate lines GL and the data lines DL. For example, the pixels PX may be disposed in a matrix form in a first direction DR1 and a second direction DR2. Each of the pixels PX may include a pixel driving circuit and a light emitting element. The light emitting element may emit light. The light emitting element may be an organic light emitting diode or an inorganic light emitting diode.

Each of the gate lines GL and each of the data lines DL may cross each other. For example, each of the gate lines GL may generally extend in the first direction DR1, and the gate lines GL may be arranged in the second direction DR2. Each of the data lines DL may generally extend in the second direction DR2, and the data lines DL may be arranged in the first direction DR1. However, the disclosure is not limited thereto.

The data driver DDV may be disposed in the peripheral area NDA on the substrate SUB. The data driver DDV may generate data voltages. The data driver DDV may output the data voltages to the data lines DL. The data voltages may be applied to the pixels PX through the data lines DL.

In an embodiment, the data driver DDV may be mounted on the substrate SUB. However, the disclosure is not limited thereto, and the data driver DDV may be disposed on a flexible film coupled to the substrate SUB. For example, the display device DD (or DDa) may have a chip on film (COF) structure.

In an embodiment, the display device DDa of FIG. 1B may include multiple data drivers DDV. For example, the data drivers DDV may be disposed on both sides of the display area DA in the second direction DR2. For example, the data drivers DDV may be disposed on each of long sides of the display device DDa. However, the disclosure is not limited thereto.

The gate driver GDV may be disposed in the peripheral area NDA on the substrate SUB. The gate driver GDV may generate gate signals. The gate driver GDV may output the gate signals to the gate lines GL. The gate signals may be applied to the pixels PX through the gate lines GL. In an embodiment, gate drivers GDV may be disposed on both sides of the display area DA in the first direction DR1. However, the disclosure is not limited thereto.

In an embodiment, an emission driver (not illustrated) generating emission control signals may be further disposed in the peripheral area NDA. The emission control signals may be applied to the pixels PX through emission control lines (not illustrated).

The number or arrangement of the data drivers DDV and the number or arrangement of the gate drivers GDVs illustrated in FIGS. 1A and 1B are merely examples, and the disclosure is not limited thereto.

Although FIG. 1A illustrates that the display device DD has a substantially rectangular planar shape having short sides each extending in the first direction DR1 and long sides each extending in the second direction DR2 in a plan view, the disclosure is not limited thereto. Although FIG. 1B illustrates that the display device DDa has a substantially rectangular planar shape having long sides each extending in the first direction DR1 and short sides each extending in the second direction DR2 in a plan view, the disclosure is not limited thereto. For example, the planar shape of each of the display devices DD and DDa may be variously changed according to embodiments.

Descriptions below with the drawings may be substantially equally applied to the display device DD of FIG. 1A and the display device DDa of FIG. 1B. Therefore, for the convenience of description, the display devices DD and DDa are both referred to as the display device DD below.

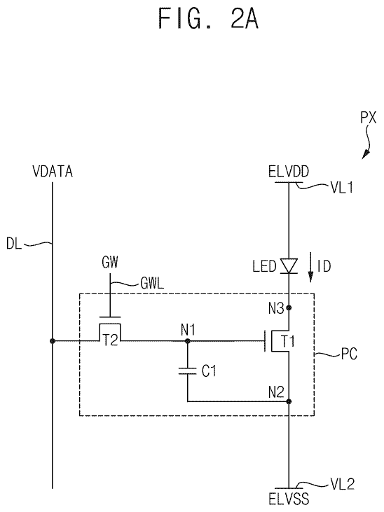

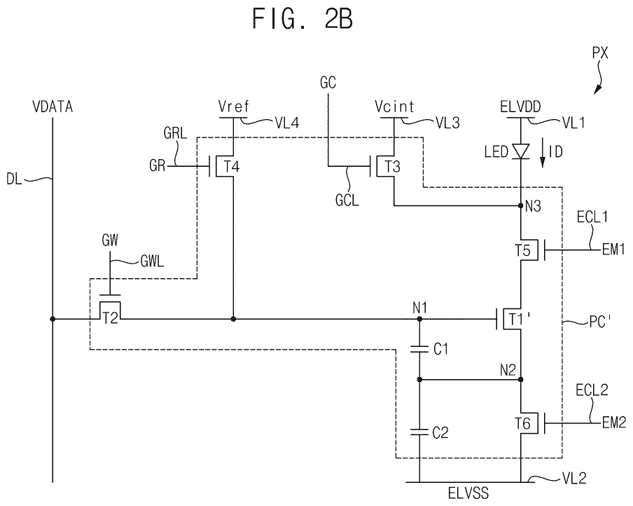

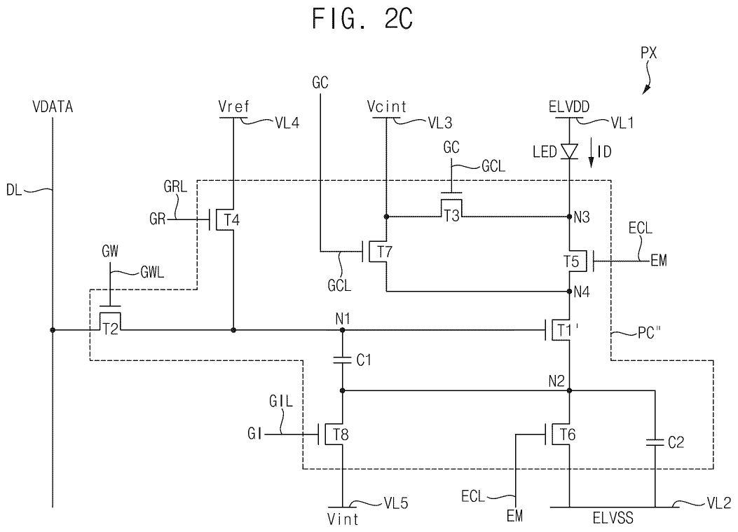

FIG. 2A is a schematic diagram of an equivalent circuit illustrating a circuit structure of a pixel included in the display device of FIGS. 1A and 1B according to an embodiment.

Referring to FIG. 2A, in an embodiment, the pixel PX may include a light emitting element LED and a pixel driving circuit PC connected to the light emitting element LED. In an embodiment, the pixel driving circuit PC may include a first transistor T1, a second transistor T2, and a first capacitor C1. In FIG. 2A, both the first transistor T1 and the second transistor T2 are illustrated as n-type transistors. However, the disclosure is not limited thereto, and some of the first transistor T1 and the second transistor T2 may be n-type transistors, and others may be p-type transistors. For example, the first transistor T1 may be the n-type transistor, and the second transistor T2 may be the p-type transistor.

In case that the pixel PX includes an n-type transistor and a p-type transistor, an active pattern of the n-type transistor may include an oxide semiconductor material, and an active pattern of the p-type transistor may include a silicon semiconductor material. However, the disclosure is not limited thereto, and both of the active pattern of the n-type transistor and the active pattern of the p-type transistor may include a silicon semiconductor material.

The pixel driving circuit PC may be connected to a first gate line GWL, a data line DL, a first voltage line VL1, and a second voltage line VL2. The first gate line GWL may transfer a first gate signal GW. The data line DL may transfer a data voltage VDATA. The first voltage line VL1 may transfer a first power voltage ELVDD having a relatively high voltage level. The second voltage line VL2 may transfer a second power voltage ELVSS having a relatively low voltage level lower than the first power voltage ELVDD.

The first transistor T1 may include a gate terminal, a first terminal, and a second terminal. In an embodiment, the first terminal of the first transistor T1 may be a source, and the second terminal of the first transistor T1 may be a drain. The gate terminal of the first transistor T1 may be connected to a first node N1. The first terminal of the first transistor T1 may be connected to a second node N2. The second terminal of the first transistor T1 may be connected to a third node N3. The second terminal of the first transistor T1 may be connected to the light emitting element LED. The first transistor T1 may provide a driving current ID to the light emitting element LED.

The second transistor T2 may include a gate terminal, a first terminal, and a second terminal. In an embodiment, the first terminal of the second transistor T2 may be a source, and the second terminal of the second transistor T2 may be a drain. However, the disclosure is not limited thereto, and the first terminal of the second transistor T2 may be a drain, and the second terminal of the second transistor T2 may be a source. The gate terminal of the second transistor T2 may be connected to the first gate line GWL. The first terminal of the second transistor T2 may be connected to the data line DL. The second terminal of the second transistor T2 may be connected to the first node N1.

The gate terminal of the second transistor T2 may receive the first gate signal GW through the first gate line GWL. The second transistor T2 may be turned on or off in response to the first gate signal GW. For example, in case that the second transistor T2 is the n-type transistor, the second transistor T2 may be turned off in case that the first gate signal GW has a negative voltage level, and the second transistor T2 may be turned on in case that the first gate signal GW has a positive voltage level. In case that the second transistor T2 is the p-type transistor, the second transistor T2 may be turned off in case that the first gate signal GW has a positive voltage level, and the second transistor T2 may be turned on in case that the first gate signal GW has a negative voltage level. The first terminal of the second transistor T2 may receive the data voltage VDATA through the data line DL. The second terminal of the second transistor T2 may provide the data voltage VDATA to the first node N1 in case that the second transistor T2 is turned on. Accordingly, the second transistor T2 may drive the first transistor T1.

The first capacitor C1 may include a first terminal and a second terminal. The first terminal of the first capacitor C1 may be connected to the first node N1. The second terminal of the first capacitor C1 may be connected to the second node N2. Current may be charged in or discharged from the first capacitor C1 according to the data voltage VDATA transferred to the first node N1.

The light emitting element LED may include an anode and a cathode. The anode of the light emitting element LED may be connected to the first voltage line VL1. The cathode of the light emitting element LED may be connected to the third node N3. For example, the cathode of the light emitting element LED may be connected to the second terminal of the first transistor T1.

FIG. 2B is a schematic diagram of an equivalent circuit illustrating a circuit structure of a pixel included in the display device of FIGS. 1A and 1B according to an embodiment.

Compared to the embodiment of the circuit structure of the pixel PX described with reference to FIG. 2A, a pixel driving circuit PC′ according to an embodiment of the circuit structure of the pixel PX described below with reference to FIG. 2B may further include third to sixth transistors T3, T4, T5, and T6 and a second capacitor C2. Therefore, repeated descriptions may be omitted or simplified.

Referring to FIG. 2B, in an embodiment, the pixel PX may include a light emitting element LED and a pixel driving circuit PC′ connected to the light emitting element LED. In an embodiment, the pixel driving circuit PC′ may include first to sixth transistors T1, T2, T3, T4, T5, and T6, a first capacitor C1, and a second capacitor C2. In FIG. 2B, all of the first to sixth transistors T1′, T2, T3, T4, T5, and T6 are illustrated as n-type transistors. However, the disclosure is not limited thereto, and some of the first to sixth transistors T1′, T2, T3, T4, T5, and T6 may be n-type transistors, and others may be p-type transistors. For example, the first transistor T1′ may be an n-type transistor, some of the second to sixth transistors T2, T3, T4, T5, and T6 may be an n-type transistors, and others may be the p-type transistors.

In case that the pixel PX includes an n-type transistor and a p-type transistor, an active pattern of the n-type transistor may include an oxide semiconductor material, and an active pattern of the p-type transistor may include a silicon semiconductor material. However, the disclosure is not limited thereto, and both the active pattern of the n-type transistor and the active pattern of the p-type transistor may include a silicon semiconductor material.

The pixel driving circuit PC′ may be connected to first to third gate lines GWL, GCL, and GRL, a data line DL, first to fourth voltage lines VL1, VL2, VL3, and VL4, a first emission control line ECL1, and a second emission control line ECL2. The first gate line GWL may transfer a first gate signal GW. The second gate line GCL may transfer a second gate signal GC. The third gate line GRL may transfer a third gate signal GR. The data line DL may transfer a data voltage VDATA. The first voltage line VL1 may transfer a first power voltage ELVDD having a relatively high voltage level. The second voltage line VL2 may transfer a second power voltage ELVSS having a relatively low voltage level lower than the first power voltage ELVDD. The third voltage line VL3 may transfer a first initialization voltage Vcint. The fourth voltage line VL4 may transfer a reference voltage Vref. The reference voltage Vref may have a voltage level lower than a voltage level of the first power voltage ELVDD.

The first transistor T1′ of FIG. 2B may be substantially the same as the first transistor T1 described above with reference to FIG. 2A, except that the second terminal of the first transistor T1′ of FIG. 2B is connected to the light emitting element LED through the fifth transistor T5. Therefore, repeated descriptions may be omitted or simplified. For example, the first transistor T1′ of the pixel driving circuit PC′ may be connected to the light emitting element LED through the fifth transistor T5 and may provide the driving current ID to the light emitting element LED through the fifth transistor T5.

The second transistor T2 of FIG. 2B may be substantially the same as the second transistor T2 described above with reference to FIG. 2A. Accordingly, the description of the second transistor T2 of FIG. 2A may be equally applied to the second transistor T2 of FIG. 2B. For example, the second transistor T2 may drive the first transistor T1′ while the second transistor T2 is turned on.

The third transistor T3 may include a gate terminal, a first terminal, and a second terminal. In an embodiment, the first terminal of the third transistor T3 may be a source, and the second terminal of the third transistor T3 may be a drain. However, the disclosure is not limited thereto, and the first terminal of the third transistor T3 may be a drain, and the second terminal of the third transistor T3 may be a source. The gate terminal of the third transistor T3 may be connected to the second gate line GCL. The first terminal of the third transistor T3 may be connected to the third node N3. The second terminal of the third transistor T3 may be connected to the third voltage line VL3.

The gate terminal of the third transistor T3 may receive the second gate signal GC through the second gate line GCL. The third transistor T3 may be turned on or off in response to the second gate signal GC. For example, in case that the third transistor T3 is the n-type transistor, the third transistor T3 may be turned off in case that the second gate signal GC has a negative voltage level, and the third transistor T3 may be turned on in case that the second gate signal GC has a positive voltage level. In case that the third transistor T3 is the p-type transistor, the third transistor T3 may be turned off in case that the second gate signal GC has a positive voltage level, and the third transistor T3 may be turned on in case that the second gate signal GC has a negative voltage level. In case that the third transistor T3 is turned on, the third transistor T3 may provide the first initialization voltage Vcint to the third node N3. For example, the third transistor T3 may initialize a voltage of the cathode by providing the first initialization voltage Vcint to the cathode of the light emitting element LED in response to the second gate signal GC.

The fourth transistor T4 may include a gate terminal, a first terminal, and a second terminal. In an embodiment, the first terminal of the fourth transistor T4 may be a source, and the second terminal of the fourth transistor T4 may be a drain. However, the disclosure is not limited thereto, and the first terminal of the fourth transistor T4 may be a drain, and the second terminal of the fourth transistor T4 may be a source. The gate terminal of the fourth transistor T4 may be connected to the third gate line GRL. The first terminal of the fourth transistor T4 may be connected to the first node N1. The second terminal of the fourth transistor T4 may be connected to the fourth voltage line VL4.

The gate terminal of the fourth transistor T4 may receive the third gate signal GR through the third gate line GRL. The fourth transistor T4 may be turned on or off in response to the third gate signal GR. For example, in case that the fourth transistor T4 is the n-type transistor, the fourth transistor T4 may be turned off in case that the third gate signal GR has a negative voltage level, and the fourth transistor T4 may be turned on in case that the third gate signal GR has a positive voltage level. In case that the fourth transistor T4 is the p-type transistor, the fourth transistor T4 may be turned off in case that the third gate signal GR has a positive voltage level, and the fourth transistor T4 may be turned on in case that the third gate signal GR has a negative voltage level. In case that the fourth transistor T4 is turned on, the fourth transistor T4 may provide the reference voltage Vref to the first node N1.

The fifth transistor T5 may include a gate terminal, a first terminal, and a second terminal. In an embodiment, the first terminal of the fifth transistor T5 may be a source, and the second terminal of the fifth transistor T5 may be a drain. However, the disclosure is not limited thereto, and the first terminal of the fifth transistor T5 may be a drain, and the second terminal of the fifth transistor T5 may be a source. The gate terminal of the fifth transistor T5 may be connected to the first emission control line ECL1. The first terminal of the fifth transistor T5 may be connected to the second terminal of the first transistor T1′. The second terminal of the fifth transistor T5 may be connected to the third node N3. The second terminal of the fifth transistor T5 may be connected to the light emitting element LED.

The gate terminal of the fifth transistor T5 may receive the first emission control signal EM1 through the first emission control line ECL1. The fifth transistor T5 may be turned on or off in response to the first emission control signal EM1. For example, in case that the fifth transistor T5 is the n-type transistor, the fifth transistor T5 may be turned off in case that the first emission control signal EM1 has a negative voltage level, and the fifth transistor T5 may be turned on in case that the first emission control signal EM1 has a positive voltage level. In case that the fifth transistor T5 is the p-type transistor, the fifth transistor T5 may be turned off in case that the first emission control signal EM1 has a positive voltage level, and the fifth transistor T5 may be turned on in case that the first emission control signal EM1 has a negative voltage level. In case that the fifth transistor T5 is turned on, the fifth transistor T5 may electrically connect the first transistor T1′ and the light emitting element LED to each other. For example, the fifth transistor T5 may electrically connect the second terminal of the first transistor T1′ and the cathode of the light emitting element LED to each other in response to the first emission control signal EM1.

The sixth transistor T6 may include a gate terminal, a first terminal, and a second terminal. In an embodiment, the first terminal of the sixth transistor T6 may be a source, and the second terminal of the sixth transistor T6 may be a drain. However, the disclosure is not limited thereto, and the first terminal of the sixth transistor T6 may be a drain, and the second terminal of the sixth transistor T6 may be a source. The gate terminal of the sixth transistor T6 may be connected to the second emission control line ECL2. The first terminal of the sixth transistor T6 may be connected to the second voltage line VL2. The second terminal of the sixth transistor T6 may be connected to the second node N2.

The gate terminal of the sixth transistor T6 may receive the second emission control signal EM2 through the second emission control line ECL2. The sixth transistor T6 may be turned on or off in response to the second emission control signal EM2. For example, in case that the sixth transistor T6 is the n-type transistor, the sixth transistor T6 may be turned off in case that the second emission control signal EM2 has a negative voltage level, and the sixth transistor T6 may be turned on in case that the second emission control signal EM2 has a positive voltage level. In case that the sixth transistor T6 is the p-type transistor, the sixth transistor T6 may be turned off in case that the second emission control signal EM2 has a positive voltage level, and the sixth transistor T6 may be turned on in case that the second emission control signal EM2 has a negative voltage level. In case that the sixth transistor T6 is turned on, the sixth transistor T6 may provide the second power voltage ELVSS to the second node N2.

Although FIG. 2B illustrates that the fifth transistor T5 and the sixth transistor T6 are independently driven by different emission control signals, the disclosure is not limited thereto. In another embodiment, the first emission control signal EM1 and the second emission control signal EM2 may be provided as a substantially single emission control signal, and the fifth transistor T5 and the sixth transistor T6 may be simultaneously turned on or off, and the first emission control line ECL1 and the second emission control line ECL2 may be provided as a substantially single emission control line.

The first capacitor C1 of FIG. 2B may be substantially the same as the first capacitor Cl described above with reference to FIG. 2A. Accordingly, the description of the first capacitor C1 of FIG. 2A may be equally applied to the first capacitor C1 of FIG. 2B. For example, current may be charged in or discharged from the first capacitor C1 according to the data voltage VDATA transferred to the first node N1.

The second capacitor C2 may include a first terminal and a second terminal. The first terminal of the second capacitor C2 may be connected to the second node N2. The second terminal of the second capacitor C2 may be connected to the second voltage line VL2. For example, the second capacitor C2 may be connected in series to the first capacitor C1. The data voltage VDATA may be transferred to the first node N1 and may be voltage-divided due to the serial connection between the first capacitor C1 and the second capacitor C2 so that the divided data voltage VDATA may be transferred to the second node N2. Since the first transistor T1′ generates the driving current ID based on a voltage of the first node N1 and a voltage of the second node N2, a data range may be extended.

The light emitting element LED of FIG. 2B may be substantially the same as the light emitting element LED described above with reference to FIG. 2A, except that the cathode is connected to the second terminal of the first transistor T1′ through the fifth transistor T5. Therefore, repeated descriptions may be omitted or simplified. For example, the cathode of the light emitting element LED may be connected to the second terminal of the first transistor T1′ through the fifth transistor T5, and the cathode of the light emitting element LED may receive the first initialization voltage Vcint through the third transistor T3.

FIG. 2C is a schematic diagram of an equivalent circuit illustrating a circuit structure of a pixel included in the display device of FIGS. 1A and 1B according to an embodiment.

Compared to the embodiment of the circuit structure of the pixel PX described with reference to FIG. 2B, a pixel driving circuit PC″ according to an embodiment of the circuit structure of the pixel PX described below with reference to FIG. 2C may further include seventh and eighth transistors T7 and T8. Therefore, repeated descriptions may be omitted or simplified.

Referring to FIG. 2C, in an embodiment, the pixel PX may include a light emitting element LED and a pixel driving circuit PC″ connected to the light emitting element LED. In an embodiment, the pixel driving circuit PC″ may include first to eighth transistors T1′, T2, T3, T4, T5, T6, T7, and T8, a first capacitor C1, and a second capacitor C2. In FIG. 2C, all of the first to eighth transistors T1′, T2, T3, T4, T5, T6, T7, and T8 are illustrated as n-type transistors. However, the disclosure is not limited thereto, and some of the first to eighth transistors T1′, T2, T3, T4, T5, T6, T7, and T8 may be n-type transistors, and others may be p-type transistors. For example, the first transistor T1′ may be an n-type transistor, some of the second to eighth transistors T2, T3, T4, T5, T6, T7, and T8 may be n-type transistors, and others may be p-type transistors.

In case that the pixel PX includes an n-type transistor and a p-type transistor, an active pattern of the n-type transistor may include an oxide semiconductor material, and an active pattern of the p-type transistor may include a silicon semiconductor material. However, the disclosure is not limited thereto, and both the active pattern of the n-type transistor and the active pattern of the p-type transistor may include a silicon semiconductor material.

The pixel driving circuit PC″ may be connected to first to fourth gate lines GWL, GCL, GRL, and GIL, a data line DL, first to fifth voltage lines VL1, VL2, VL3, VL4, and VL5, and an emission control line ECL. The first gate line GWL may transfer a first gate signal GW. The second gate line GCL may transfer a second gate signal GC. The third gate line GRL may transfer a third gate signal GR. The fourth gate line GIL may transfer a fourth gate signal GI. The data line DL may transfer a data voltage VDATA. The first voltage line VL1 may transfer a first power voltage ELVDD having a relatively high voltage level. The second voltage line VL2 may transfer a second power voltage ELVSS having a relatively low voltage level lower than the first power voltage ELVDD. The third voltage line VL3 may transfer a first initialization voltage Vcint. The fourth voltage line VL4 may transfer a reference voltage Vref. The reference voltage Vref may have a voltage level lower than a voltage level of the first power voltage ELVDD. The fifth voltage line VL5 may transfer a second initialization voltage Vint. The first initialization voltage Vcint and the second initialization voltage Vint may have different voltage levels from each other.

The first to sixth transistors T1′, T2, T3, T4, T5, and T6, the first capacitor C1, and the second capacitor C2 of FIG. 2C may be substantially the same as the first to sixth transistors T1′, T2, T3, T4, T5, and T6, the first capacitor C1, and the second capacitor C2 described above with reference to FIG. 2B, respectively. Accordingly, the descriptions of the first to sixth transistors T1′, T2, T3, T4, T5, and T6, the first capacitor C1, and the second capacitor C2 of FIG. 2B may be equally applied to the first to sixth transistors T1′, T2, T3, T4, T5, and T6, the first capacitor C1, and the second capacitor C2 of FIG. 2C, respectively. Therefore, repeated descriptions may be omitted.

Although FIG. 2C illustrates that the fifth transistor T5 and the sixth transistor T6 are simultaneously driven by the emission control signal EM, the disclosure is not limited thereto. In another embodiment, as in FIG. 2B, the fifth transistor T5 and the sixth transistor T6 may be independently driven by different emission control signals (e.g., the first emission control signal EM1 and the second emission control signal EM2 of FIG. 2B), and the emission control line connected to the fifth transistor T5 and the emission control line connected to the sixth transistor T6 may be different emission control lines (e.g., the first emission control line ECL1 and the second emission control line ECL2 of FIG. 2B) that are distinct from each other.

The seventh transistor T7 may include a gate terminal, a first terminal, and a second terminal. In an embodiment, the first terminal of the seventh transistor T7 may be a source, and the second terminal of the seventh transistor T7 may be a drain. However, the disclosure is not limited thereto, and the first terminal of the seventh transistor T7 may be a drain, and the second terminal of the seventh transistor T7 may be a source. The gate terminal of the seventh transistor T7 may be connected to the second gate line GCL. The first terminal of the seventh transistor T7 may be connected to a fourth node N4. The second terminal of the seventh transistor T7 may be connected to the third voltage line VL3.

The gate terminal of the seventh transistor T7 may receive the second gate signal GC through the second gate line GCL. The seventh transistor T7 may be turned on or off in response to the second gate signal GC. For example, in case that the seventh transistor T7 is the n-type transistor, the seventh transistor T7 may be turned off in case that the second gate signal GC has a negative voltage level, and the seventh transistor T7 may be turned on in case that the second gate signal GC has a positive voltage level. In case that the seventh transistor T7 is the p-type transistor, the seventh transistor T7 may be turned off in case that the second gate signal GC has a positive voltage level, and the seventh transistor T7 may be turned on in case that the second gate signal GC has a negative voltage level. In case that the seventh transistor T7 is turned on, the seventh transistor T7 may provide the first initialization voltage Vcint to the fourth node N4. For example, the seventh transistor T7 may compensate for a threshold voltage (Vth) of the first transistor T1′ by providing the first initialization voltage Vcint to the fourth node N4 in response to the second gate signal GC.

Although FIG. 2C illustrates that the gate line connected to the third transistor T3 and the gate line connected to the seventh transistor T7 are provided as a single gate line (i.e., the second gate line GCL), the disclosure is not limited thereto. In another embodiment, the gate line connected to the third transistor T3 and the gate line connected to the seventh transistor T7 may be different gate lines that are distinct from each other.

Although FIG. 2C illustrates that the third transistor T3 and the seventh transistor T7 are simultaneously driven by the second gate signal GC, the disclosure is not limited thereto. In another embodiment, the third transistor T3 and the seventh transistor T7 may be independently driven by different gate signals, and the gate line connected to the third transistor T3 and the gate line connected to the seventh transistor T7 may be different gate lines that are distinct from each other.

The eighth transistor T8 may include a gate terminal, a first terminal, and a second terminal. In an embodiment, the first terminal of the eighth transistor T8 may be a source, and the second terminal of the eighth transistor T8 may be a drain. However, the disclosure is not limited thereto, and the first terminal of the eighth transistor T8 may be a drain, and the second terminal of the eighth transistor T8 may be a source. The gate terminal of the eighth transistor T8 may be connected to the fourth gate line GIL. The first terminal of the eighth transistor T8 may be connected to the second node N2. The second terminal of the eighth transistor T8 may be connected to the fifth voltage line VL5.

The gate terminal of the eighth transistor T8 may receive the fourth gate signal GI through the fourth gate line GIL. The eighth transistor T8 may be turned on or off in response to the fourth gate signal GI. For example, in case that the eighth transistor T8 is the n-type transistor, the eighth transistor T8 may be turned off in case that the fourth gate signal GI has a negative voltage level, and the eighth transistor T8 may be turned on in case that the fourth gate signal GI has a positive voltage level. In case that the eighth transistor T8 is the p-type transistor, the eighth transistor T8 may be turned off in case that the fourth gate signal GI has a positive voltage level, and the eighth transistor T8 may be turned on in case that the fourth gate signal GI has a negative voltage level. In case that the eighth transistor T8 is turned on, the eighth transistor T8 may provide the second initialization voltage Vint to the second node N2

The light emitting element LED of FIG. 2C may be substantially the same as the light emitting element LED described above with reference to FIG. 2B. Accordingly, the description of the light emitting element LED of FIG. 2B may be equally applied to the light emitting element LED of FIG. 2C. Therefore, repeated descriptions may be omitted.

As illustrated in FIGS. 2A to 2C, according to embodiments, the anode of the light emitting element LED may receive the first power voltage ELVDD through the first voltage line VL1, and the cathode of the light emitting element LED may be connected to the second terminal of the first transistor T1 (or T1′). For example, a potential of the cathode of the light emitting element LED may be controlled by being electrically connected to the first transistor T1 (or T1′).

Since the first voltage line VL1 provides the first power voltage ELVDD having a relatively high voltage level and the second voltage line VL2 provides the second power voltage ELVSS having a relatively low voltage level, in case that the first transistor T1 (or T1′) is an n-type transistor, the second terminal of the first transistor T1 (or T1′) may be a drain. According to embodiments, the cathode of the light emitting element LED may be connected to the drain of the first transistor T1 (or T1′).

In case that the first transistor T1 (or T1′) is an n-type transistor, if the anode of the light emitting element LED is connected to the source of first transistor T1 (or T1′), a source voltage of the first transistor T1 (or T1′) may shift due to deterioration of the light emitting element LED so that a gate-source voltage (Vgs) of the first transistor T1 (or T1′) may change. As a result, a range of change in the driving current ID may increase, an after-image defect may occur, and a lifespan of the display device may be reduced.

According to embodiments, the anode of the light emitting element LED may receive the first power voltage ELVDD, and the cathode of the light emitting element LED may be connected to the drain of the first transistor T1 (or T1′). Accordingly, even in case that the light emitting element LED deteriorates, the gate-source voltage (Vgs) of the first transistor T1 (or T1′) may not change. Accordingly, the range of change in the driving current ID due to the deterioration of the light emitting element LED may be reduced. Therefore, the after-image defect of the display device DD depending on an increase in the time of use may be reduced, and the lifespan of the display device DD may be improved.

The circuit structures of the pixels (e.g., the number or arrangement of the transistors, the number or arrangement of the capacitors) are not limited to the embodiment illustrated in FIGS. 2A to 2C, and may be variously changed according to embodiments.

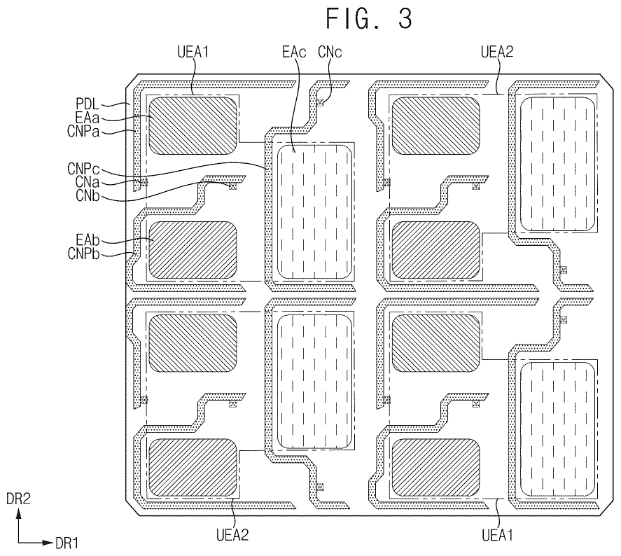

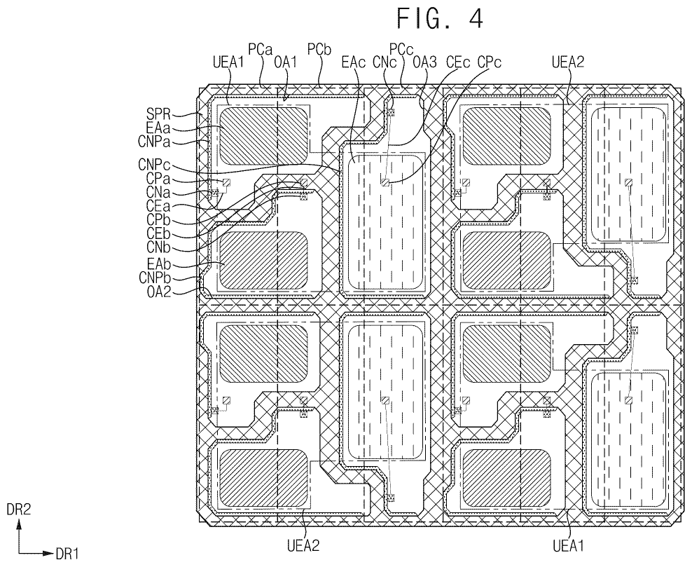

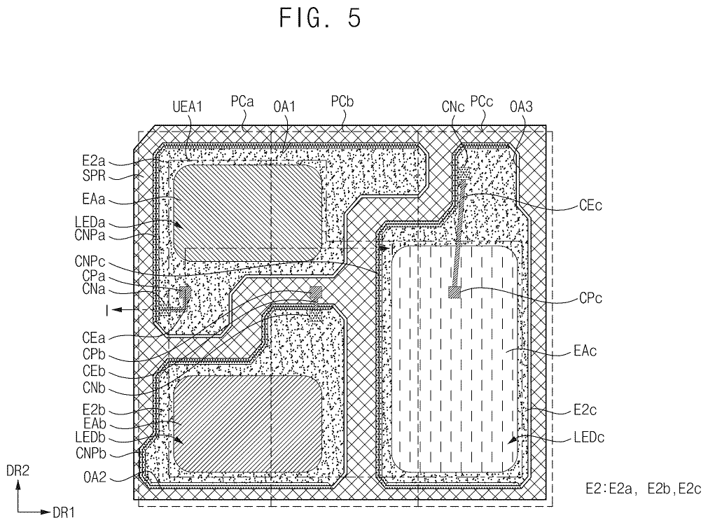

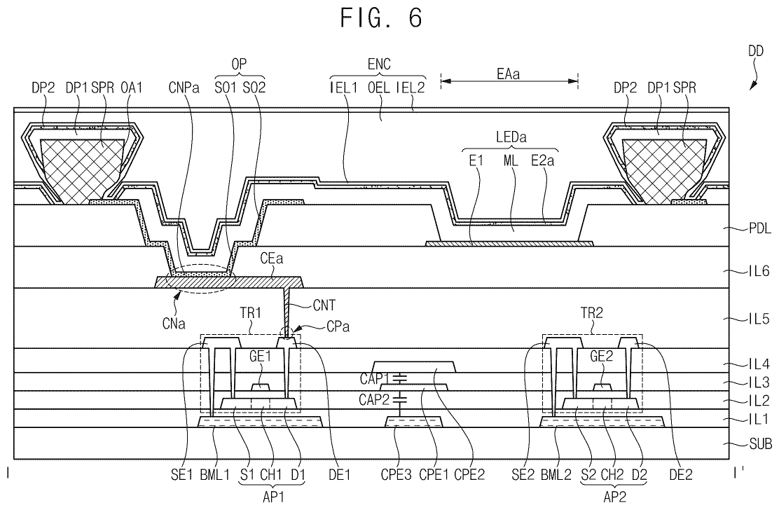

FIGS. 3 and 4 are plan views schematically illustrating a portion of the display device of FIGS. 1A and 1B according to an embodiment. FIG. 5 is an enlarged view illustrating one of unit emission areas of FIG. 4 according to an embodiment. FIG. 6 is a schematic cross-sectional view taken along line I-I′ of FIG. 5 according to an embodiment.

For example, FIGS. 3 and 4 schematically illustrate an area in which four unit emission areas UEA1 and UEA2 forming a matrix of two rows and two columns are arranged, and FIG. 5 schematically illustrates an enlarged view of a first unit emission area UEA1 among the unit emission areas UEA1 and UEA2.

For convenience of description, some of components illustrated in FIG. 6 are omitted or emphasized in FIGS. 3 to 5. For example, FIG. 3 is a plan view illustrating first to third connection patterns CNPa, CNPb, and CNPc disposed on a pixel defining layer PDL, and FIG. 4 is a plan view illustrating a state in which a separator SPR is disposed on the pixel defining layer PDL and the first to third connection patterns CNPa, CNPb, and CNPc of FIG. 3. First to third pixel driving circuits PCa, PCb, and PCc, first to third connection electrodes CEa, CEb, and CEc, and the separator SPR among components illustrated in FIG. 4 are omitted in FIG. 3. Second electrodes E2a, E2b, and E2c among components illustrated in FIG. 5 are also omitted in FIG. 4.

Referring to FIGS. 3 to 5, the display device DD may include first to third pixel driving circuits PCa, PCb, and PCc, first to third light emitting elements LEDa, LEDb, and LEDc, first to third connection electrodes CEa, CEb, and CEc, first to third connection patterns CNPa, CNPb, and CNPc, and a separator SPR.

Each of the first to third pixel driving circuits PCa, PCb, and PCc may correspond to at least one of the pixel driving circuits PC, PC′, and PC′ described above with reference to FIGS. 2A to 2C. For example, each of the first to third pixel driving circuits PCa, PCb, and PCc may include at least one transistor and at least one capacitor. For example, each of the first to third pixel driving circuits PCa, PCb, and PCc may include a first transistor TR1, a second transistor TR2, a first capacitor CAP1, and a second capacitor CAP2 illustrated in FIG. 6.

The first transistor TR1 of FIG. 6 may be a transistor connected to the light emitting element through a connection electrode and a connection pattern. For example, in case that each of the first to third pixel driving circuits PCa, PCb, and PCc is the pixel driving circuit PC of FIG. 2A, the first transistor TR1 may be the first transistor T1 of FIG. 2A, and the second transistor TR2 may be the second transistor T2 of FIG. 2A. In case that each of the first to third pixel driving circuits PCa, PCb, and PCc is the pixel driving circuits PC′ of FIG. 2B, the first transistor TR1 may be the fifth transistor T5 of FIG. 2B, and the second transistor TR2 may be one of the first, second, third, fourth, and sixth transistors T1′, T2, T3, T4, and T6 of FIG. 2B. In case that each of the first to third pixel driving circuits PCa, PCb, and PCc is the pixel driving circuits PC″ of FIG. 2C, the first transistor TR1 may be the fifth transistor T5 of FIG. 2C, and the second transistor TR2 may be one of the first, second, third, fourth, sixth, seventh, and eighth transistors T1′, T2, T3, T4, T6, T7, and T8 of FIG. 2C. However, the disclosure is not limited thereto.

In an embodiment, the first capacitor CAP1 of FIG. 6 may correspond to the first capacitor C1 of FIGS. 2A to 2C, and the second capacitor CAP2 of FIG. 6 may correspond to the second capacitor C2 of FIGS. 2B and 2C. For example, in case that each of the first to third pixel driving circuits PCa, PCb, and PCc is the pixel driving circuits PC of FIG. 2A, the second capacitor CAP2 may be omitted. However, the disclosure is not limited thereto, and in an embodiment, the first capacitor CAP1 of FIG. 6 may correspond to the second capacitor C2 of FIGS. 2B and 2C, and the second capacitor CAP2 of FIG. 6 may correspond to the first capacitor C1 of FIGS. 2A to 2C. In case that each of the first to third pixel driving circuits PCa, PCb, and PCc is the pixel driving circuits PC of FIG. 2A, the first capacitor CAP1 may be omitted.

The first transistor TR1, the second transistor TR2, the first capacitor CAP1, and the second capacitor CAP2 will be described in more detail later with reference to FIG. 6.

FIGS. 4 and 5 illustrate that the first to third pixel driving circuits PCa, PCb, and PCc each have a rectangular shape and are sequentially disposed in the first direction DR1 in a plan view. However, the disclosure is not limited thereto, and the shape and arrangement of the first to third pixel driving circuits PCa, PCb, and PCc may be variously changed according to embodiments.

Each of the first to third light emitting elements LEDa, LEDb, and LEDc may correspond to the light emitting element LED described above with reference to FIGS. 2A to 2C. For example, the first to third light emitting elements LEDa, LEDb, and LEDc may include a first electrode (e.g., a first electrode E1 of FIG. 6), an intermediate layer (e.g., an intermediate layer ML of FIG. 6) disposed on the first electrode, and an electrode layer E2 disposed on the intermediate layer. In an embodiment, the first electrode may function as the anode of FIGS. 2A to 2C, and the electrode layer E2 may function as the cathode of FIGS. 2A to 2C.

In an embodiment, as illustrated in FIG. 5, the electrode layer E2 may be separated (or disconnected) into second electrodes E2a, E2b, and E2c by the separator SPR. For example, the electrode layer E2 may be separated (or disconnected) into the second electrode E2a of the first light emitting element LEDa, the second electrode E2b of the second light emitting element LEDb, and the second electrode E2c of the third light emitting element LEDc, and the second electrodes E2a, E2b, and E2c may be electrically insulated from each other. This will be described in more detail below.

The first to third light emitting elements LEDa, LEDb, and LEDc may emit light of different colors. For example, the first light emitting element LEDa may emit red light, the second light emitting element LEDb may emit green light, and the third light emitting element LEDc may emit blue light. However, the disclosure is not limited thereto.

In an embodiment, the display device DD may include the first unit emission area UEA1 and the second unit emission area UEA2. The first unit emission area UEA1 and the second unit emission area UEA2 may be defined in a matrix form in the first direction DR1 and the second direction DR2. Although FIGS. 3 and 4 illustrate only four unit emission areas, multiple unit emission areas may be defined in a matrix form in the first direction DR1 and the second direction DR2 in the entire display area DA (see FIGS. 1A and 1B).

The first to third light emitting elements LEDa, LEDb, and LEDc adjacent to each other may be disposed in each of the first unit emission area UEA1 and the second unit emission area UEA2. For example, first to third emission areas EAa, EAb, and EAc adjacent to each other may be defined in each of the first unit emission area UEA1 and the second unit emission area UEA2, and the first to third light emitting elements LEDa, LEDb, and LEDc may be disposed in the first to third emission areas EAa, EAb, and EAc, respectively.

The first to third emission areas EAa, EAb, and EAc may be defined by pixel openings of the pixel defining layer PDL. Each of the first to third emission areas EAa, EAb, and EAc may be an area where light is emitted from the light emitting element. For example, the first light emitting element LEDa may be disposed in the first emission area EAa, and the first emission area EAa may be an area where light is emitted from the first light emitting element LEDa. For example, the second light emitting element LEDb may be disposed in the second emission area EAb, and the second emission area EAb may be an area where light is emitted from the second light emitting element LEDb. For example, the third light emitting element LEDc may be disposed in the third emission area EAc, and the third emission area EAc may be an area where light is emitted from the third light emitting element LEDc.

In an embodiment, the first unit emission area UEA1 and the second unit emission area UEA2 may be distinguished based on the arrangement of the first to third light emitting elements LEDa, LEDb, and LEDc (or the arrangement of the first to third emission areas EAa, EAb, and EAc). For example, the arrangement of the first to third light emitting elements LEDa, LEDb, and LEDc (or the first to third emission areas EAa, EAb, and EAc) may be the same for each first unit emission area UEA1, and the arrangement of the first to third light emitting elements LEDa, LEDb, and LEDc (or the first to third emission areas EAa, EAb, and EAc) may be the same for each second unit emission area UEA2.

As illustrated in FIGS. 3 and 4, in an embodiment, the first unit emission areas UEA1 and the second unit emission areas UEA2 may be alternately disposed in the first direction DR1 (i.e., a row direction) and the second direction DR2 (i.e., a column direction). However, the disclosure is not limited thereto, and the number of different unit emission areas included in the display device DD or the arrangement of the unit emission areas may be variously changed according to embodiments.

FIGS. 3 to 5 illustrate that the first to third emission areas EAa, EAb, and EAc are disposed in an S-stripe structure. However, the disclosure is not limited thereto, and the arrangement of the first to third emission areas EAa, EAb, and EAc may be variously changed according to embodiments.

The first to third light emitting elements LEDa, LEDb, and LEDc may be connected to the first to third pixel driving circuits PCa, PCb, and PCc, respectively. For example, the first light emitting element LEDa may be connected to the first pixel driving circuit PCa, the second light emitting element LEDb may be connected to the second pixel driving circuit PCb, and the third light emitting element LEDc may be connected to the third pixel driving circuit PCc. Accordingly, the first pixel driving circuit PCa and the first light emitting element LEDa may form one pixel, the second pixel driving circuit PCb and the second light emitting element LEDb may form one pixel, and the third pixel driving circuit PCc and the third light emitting element LEDc may form one pixel.

Hereinafter, a connection relationship between the first to third light emitting elements LEDa, LEDb, and LEDc and the first to third pixel driving circuits PCa, PCb, and PCc will be described in more detail, focusing on the first unit emission area UEA1 of FIG. 5. The following description of the connection relationship between the first to third light emitting elements LEDa, LEDb, and LEDc and the first to third pixel driving circuits PCa, PCb, and PCc may be substantially equally applied to all unit emission areas.

As described above, the display device DD may include the first to third connection electrodes CEa, CEb, and CEc and the first to third connection patterns CNPa, CNPb, and CNPc. The first connection electrode CEa and the first connection pattern CNPa may connect the first light emitting element LEDa and the first pixel driving circuit PCa to each other, the second connection electrode CEb and the second connection pattern CNPb may connect the second light emitting element LEDb and the second pixel driving circuit PCb to each other, and the third connection electrode CEc and the third connection pattern CNPc may connect the third light emitting element LEDc and the third pixel driving circuit PCc to each other.

The first to third connection electrodes CEa, CEb, and CEc may include a conductive material such as a metal, an alloy, a conductive metal oxide, a conductive metal nitride, a transparent conductive oxide, or the like. For example, the first to third connection electrodes CEa, CEb, and CEc may include at least one of gold (Au), silver (Ag), aluminum (Al), platinum (Pt), nickel (Ni), titanium (Ti), palladium (Pd), magnesium (Mg), calcium (Ca), lithium (Li), chromium (Cr), tantalum (Ta), tungsten (W), copper (Cu), molybdenum (Mo), scandium (Sc), neodymium (Nd), iridium (Ir), an alloy containing Al, an alloy containing Ag, an alloy containing Cu, an alloy containing Mo, aluminum nitride (AlN), tungsten nitride (WN), titanium nitride (TiN), chromium nitride (CrN), tantalum nitride (TaN), tin oxide (SnO), gallium oxide (GaO), indium gallium zinc oxide (IGZO), indium tin zinc oxide (ITZO), indium tin oxide (ITO), indium zinc oxide (IZO), indium gallium oxide (IGO), zinc oxide (ZnO), indium oxide (InO), aluminum zinc oxide (AZO), and the like. These may be used alone or in combination with each other. In an embodiment, each of the first to third connection electrodes CEa, CEb, and CEc may have a single-layer structure or a multi-layer structure in which multiple conductive layers are stacked each other.

The first to third connection patterns CNPa, CNPb, and CNPc may include a transparent conductive oxide. For example, the first to third connection patterns CNPa, CNPb, and CNPc may include at least one of IGZO, ITZO, ITO, IZO, IGO, ZnO, InO, SnO, GaO, AZO, and the like. These may be used alone or in combination with each other.

However, the disclosure is not limited thereto, and the first to third connection patterns CNPa, CNPb, and CNPc may include a conductive material such as a metal, an alloy, a conductive metal nitride, or the like. For example, the first to third connection patterns CNPa, CNPb, and CNPc may include at least one of Au, Ag, Al, Pt, Ni, Ti, Pd, Mg, Ca, Li, Cr, Ta, W, Cu, Mo, Sc, Nd, Ir, an alloy containing Al, an alloy containing Ag, an alloy containing Cu, an alloy containing Mo, AlN, WN, TiN, CrN, TaN, and the like. These may be used alone or in combination with each other.

In an embodiment, each of the first to third connection patterns CNPa, CNPb, and CNPc may have a single-layer structure or a multi-layer structure in which multiple conductive layers are stacked each other.

The first connection electrode CEa may include a first circuit connection portion CPa and a first light emitting connection portion CNa.

The first circuit connection portion CPa may be a portion, which is connected to the first pixel driving circuit PCa, of the first connection electrode CEa. For example, the first circuit connection portion CPa may be a portion, which is connected to the first transistor TR1 (see FIG. 6) of the first pixel driving circuit PCa, of the first connection electrode CEa. Accordingly, a position of the first circuit connection portion CPa may correspond to a position of the first transistor TR1 of the first pixel driving circuit PCa. For example, the position of the first circuit connection portion CPa may correspond to a position of a contact hole that exposes the first transistor TR1 of the first pixel driving circuit PCa and penetrates the fifth insulating layer IL5 (see FIG. 6).

The first light emitting connection portion CNa may be a portion, which is connected to the first connection pattern CNPa, of the first connection electrode CEa. For example, the first light emitting connection portion CNa may be a portion, which is exposed by the sixth insulating layer IL6 (see FIG. 6) and the pixel defining layer PDL for being connected to the first connection pattern CNPa, of the first connection electrode CEa. Accordingly, a position of the first light emitting connection portion CNa may correspond to a position of an opening that exposes the first connection electrode CEa and penetrates the pixel defining layer PDL and the sixth insulating layer IL6. In a plan view, the first light emitting connection portion CNa may not overlap the first emission area EAa. For example, in a plan view, the first light emitting connection portion CNa may be disposed between the first emission area EAa and the separator SPR. However, the disclosure is not limited thereto.

The first connection pattern CNPa may be connected to the first connection electrode CEa. For example, the first connection pattern CNPa may contact the first light emitting connection portion CNa of the first connection electrode CEa. However, the disclosure is not limited thereto, and the first connection pattern CNPa may not directly contact the first connection electrode CEa. For example, the first connection pattern CNPa may contact a capping layer that contacts the first light emitting connection portion CNa of the first connection electrode CEa, and may be connected to the first light emitting connection portion CNa of the first connection electrode CEa through the capping layer. The capping layer may include a conductive material. For example, the capping layer and the first electrode E1 (see FIG. 6) may be substantially simultaneously formed and may include a same material.

The first connection pattern CNPa may not overlap the first emission area EAa in a plan view. In an embodiment, the first connection pattern CNPa may partially surround the first emission area EAa in a plan view. For example, in a plan view, the first connection pattern CNPa may not surround a side, which faces the second emission area EAb, among sides of the first emission area EAa. For example, in a plan view, the first connection pattern CNPa may not be disposed between the first emission area EAa and the second emission area EAb. In a plan view, the first connection pattern CNPa may not surround a side, which faces the third emission area EAc, among the sides of the first emission area EAa. For example, in a plan view, the first connection pattern CNPa may not be disposed between the first emission area EAa and the third emission area EAc. However, the disclosure is not limited thereto.

If the first connection pattern CNPa entirely surrounds the first emission area EAa in a plan view, a degree of design freedom of the first emission area EAa may be reduced due to the first connection pattern CNPa. For example, a limitation of a size of the first emission area EAa (i.e., an aperture ratio) may occur due to the first connection pattern CNPa. According to embodiments, the first connection pattern CNPa may partially surround the first emission area EAa in a plan view. Accordingly, a limitation of a design of the first emission area EAa due to the first connection pattern CNPa may be reduced. Accordingly, the degree of design freedom of the first emission area EAa may be improved, and the size of the first emission area EAa (i.e., an aperture ratio) may be also increased.

The second electrode E2a of the first light emitting element LEDa may be connected to the first connection pattern CNPa. For example, the second electrode E2a of the first light emitting element LEDa may contact the first connection pattern CNPa. Accordingly, the first connection pattern CNPa may connect the first connection electrode CEa and the second electrode E2a of the first light emitting element LEDa to each other. As a result, the second electrode E2a of the first light emitting element LEDa may be connected to the first pixel driving circuit PCa through the first connection electrode CEa and the first connection pattern CNPa.

In an embodiment, in a plan view, a profile of an area where the second electrode E2a of the first light emitting element LEDa and the first connection pattern CNPa contact each other may be substantially the same as or similar to a profile of an edge of the first connection pattern CNPa. For example, in case that the first connection pattern CNPa partially surrounds the first emission area EAa in a plan view, the area where the second electrode E2a of the first light emitting element LEDa and the first connection pattern CNPa contact each other may partially surround the first emission area EAa in a plan view. For example, the second electrode E2a of the first light emitting element LEDa and the first connection pattern CNPa may contact each other at a position not overlapping the first emission area EAa in a plan view. Accordingly, the second electrode E2a of the first light emitting element LEDa and the first pixel driving circuit PCa may be connected to each other through the first connection pattern CNPa and the first connection electrode CEa without reducing the size of the first emission area EAa (i.e., an aperture ratio).

The second connection electrode CEb may include a second circuit connection portion CPb and a second light emitting connection portion CNb.

The second circuit connection portion CPb may be a portion, which is connected to the second pixel driving circuit PCb, of the second connection electrode CEb. For example, the second circuit connection portion CPb may be a portion, which is connected to the first transistor TR1 (corresponding to TR1 in FIG. 6) of the second pixel driving circuit PCb, of the second connection electrode CEb. Accordingly, a position of the second circuit connection portion CPb may correspond to a position of the first transistor TR1 of the second pixel driving circuit PCb. For example, the position of the second circuit connection portion CPb may correspond to a position of a contact hole that exposes the first transistor TR1 of the second pixel driving circuit PCb and penetrates the fifth insulating layer IL5 (corresponding to IL5 in FIG. 6).

The second light emitting connection portion CNb may be a portion, which is connected to the second connection pattern CNPb, of the second connection electrode CEb. For example, the second light emitting connection portion CNb may be a portion, which is exposed by the sixth insulating layer IL6 (corresponding to IL6 in FIG. 6) and the pixel defining layer PDL for being connected to the second connection pattern CNPb, of the second connection electrode CEb. Accordingly, a position of the second light emitting connection portion CNb may correspond to a position of an opening that exposes the second connection electrode CEb and penetrates the pixel defining layer PDL and the sixth insulating layer IL6. In a plan view, the second light emitting connection portion CNb may not overlap the second emission area EAb. For example, in a plan view, the second light emitting connection portion CNb may be disposed between the second emission area EAb and the separator SPR.

In an embodiment, the second connection electrode CEb may be spaced apart from the first connection electrode CEa in a plan view. In other words, the first connection electrode CEa and the second connection electrode CEb may be different electrodes that are distinct from each other.

The second connection pattern CNPb may be connected to the second connection electrode CEb. For example, the second connection pattern CNPb may contact the second light emitting connection portion CNb of the second connection electrode CEb. However, the disclosure is not limited thereto, and the second connection pattern CNPb may not directly contact the second connection electrode CEb. For example, the second connection pattern CNPb may contact a capping layer that contacts the second light emitting connection portion CNb of the second connection electrode CEb, and may be connected to the second light emitting connection portion CNb of the second connection electrode CEb through the capping layer. The capping layer may include a conductive material. For example, the capping layer and the first electrode E1 (see FIG. 6) may be substantially simultaneously formed and may include a same material.

In an embodiment, the second connection pattern CNPb may be spaced apart from the first connection pattern CNPa. In other words, the first connection pattern CNPa and the second connection pattern CNPb may be different patterns that are distinct from each other. For example, the first connection pattern CNPa and the second connection pattern CNPb may be electrically insulated from each other.

The second connection pattern CNPb may not overlap the second emission area EAb in a plan view. In an embodiment, the second connection pattern CNPb may partially surround the second emission area EAb in a plan view. For example, in a plan view, the second connection pattern CNPb may not surround a side, which faces the third emission area EAc, among sides of the second emission area EAb. For example, in a plan view, the second connection pattern CNPb may not be disposed between the second emission area EAb and the third emission area EAc. However, the disclosure is not limited thereto.

If the second connection pattern CNPb entirely surrounds the second emission area EAb in a plan view, a degree of design freedom of the second emission area EAb may be reduced due to the second connection pattern CNPb. For example, a limitation of a size of the second emission area EAb (i.e., an aperture ratio) may occur due to the second connection pattern CNPb. According to embodiments, the second connection pattern CNPb may partially surround the second emission area EAb in a plan view. Accordingly, a limitation of a design of the second emission area EAb due to the second connection pattern CNPb may be reduced. Accordingly, the degree of design freedom of the second emission area EAb may be improved, and the size of the second emission area EAb (i.e., an aperture ratio) may be also increased.

In a plan view, the second connection pattern CNPb may surround a side, which faces the first emission area EAa, among the sides of the second emission area EAb. For example, in a plan view, the second connection pattern CNPb may be disposed between the first emission area EAa and the second emission area EAb. In other words, in a plan view, the second connection pattern CNPb, or one of the first connection pattern CNPa and the second connection pattern CNPb, may be disposed between the first emission area EAa and the second emission area EAb.

The second electrode E2b of the second light emitting element LEDb may be connected to the second connection pattern CNPb. For example, the second electrode E2b of the second light emitting element LEDb may contact the second connection pattern CNPb. Accordingly, the second connection pattern CNPb may connect the second connection electrode CEb and the second electrode E2b of the second light emitting element LEDb to each other. As a result, the second electrode E2b of the second light emitting element LEDb may be connected to the second pixel driving circuit PCb through the second connection electrode CEb and the second connection pattern CNPb.

In an embodiment, in a plan view, a profile of an area where the second electrode E2b of the second light emitting element LEDb and the second connection pattern CNPb contact each other may be substantially the same as or similar to a profile of an edge of the second connection pattern CNPb. For example, in case that the second connection pattern CNPb partially surrounds the second emission area EAb in a plan view, the area where the second electrode E2b of the second light emitting element LEDb and the second connection pattern CNPb contact each other may partially surround the second emission area EAb in a plan view. For example, the second electrode E2b of the second light emitting element LEDb and the second connection pattern CNPb may contact each other at a position not overlapping the second emission area EAb in a plan view. Accordingly, the second electrode E2b of the second light emitting element LEDb and the second pixel driving circuit PCb may be connected to each other through the second connection pattern CNPb and the second connection electrode CEb without reducing the size of the second emission area EAb (i.e., an aperture ratio).

The third connection electrode CEc may include a third circuit connection portion CPc and a third light emitting connection portion CNc.

The third circuit connection portion CPc may be a portion, which is connected to the third pixel driving circuit PCc, of the third connection electrode CEc. For example, the third circuit connection portion CPc may be a portion, which is connected to the first transistor TR1 (corresponding to TR1 in FIG. 6) of the third pixel driving circuit PCc, of the third connection electrode CEc. Accordingly, a position of the third circuit connection portion CPc may correspond to a position of the first transistor TR1 of the third pixel driving circuit PCc. For example, the position of the third circuit connection portion CPc may correspond to a position of a contact hole that exposes the first transistor TR1 of the third pixel driving circuit PCc and penetrates the fifth insulating layer IL5 (corresponding to IL5 in FIG. 6).

The third light emitting connection portion CNc may be a portion, which is connected to the third connection pattern CNPc, of the third connection electrode CEc. For example, the third light emitting connection portion CNc may be a portion, which is exposed by the sixth insulating layer IL6 (corresponding to IL6 in FIG. 6) and the pixel defining layer PDL for being connected to the third connection pattern CNPc, of the third connection electrode CEc. Accordingly, a position of the third light emitting connection portion CNc may correspond to a position of an opening that exposes the third connection electrode CEc and penetrates the pixel defining layer PDL and the sixth insulating layer IL6. In a plan view, the third light emitting connection portion CNc may not overlap the third emission area EAc. For example, in a plan view, the third light emitting connection portion CNc may be disposed between the third emission area EAc and the separator SPR.

In an embodiment, the third connection electrode CEc may be spaced apart from the first connection electrode CEa and the second connection electrode CEb in a plan view. In other words, the first connection electrode CEa, the second connection electrode CEb, and the third connection electrode CEc may be different electrodes that are distinct from each other.

The third connection pattern CNPc may be connected to the third connection electrode CEc. For example, the third connection pattern CNPc may contact the third light emitting connection portion CNc of the third connection electrode CEc. However, the disclosure is not limited thereto, and the third connection pattern CNPc may not directly contact the third connection electrode CEc. For example, the third connection pattern CNPc may contact a capping layer that contacts the third light emitting connection portion CNc of the third connection electrode CEc, and may be connected to the third light emitting connection portion CNc of the third connection electrode CEc through the capping layer. The capping layer may include a conductive material. For example, the capping layer and the first electrode E1 (see FIG. 6) may be substantially simultaneously formed and may include a same material.

In an embodiment, the third connection pattern CNPc may be spaced apart from the first connection pattern CNPa and the second connection pattern CNPb. In other words, the first connection pattern CNPa, the second connection pattern CNPb, and the third connection pattern CNPc may be different patterns that are distinct from each other. For example, the first connection pattern CNPa, the second connection pattern CNPb, and the third connection pattern CNPc may be electrically insulated from each other.

The third connection pattern CNPc may not overlap the third emission area EAc in a plan view. In an embodiment, the third connection pattern CNPc may partially surround the third emission area EAc in a plan view. For example, in a plan view, the third connection pattern CNPc may not surround at least one side among sides of the third emission area EAc.

If the third connection pattern CNPc entirely surrounds the third emission area EAc in a plan view, a degree of design freedom of the third emission area EAc may be reduced due to the third connection pattern CNPc. For example, a limitation of a size of the third emission area EAc (i.e., an aperture ratio) may occur due to the third connection pattern CNPc. According to embodiments, the third connection pattern CNPc may partially surround the third emission area EAc in a plan view. Accordingly, a limitation of a design of the third emission area EAc due to the third connection pattern CNPc may be reduced. Accordingly, the degree of design freedom of the third emission area EAc may be improved, and the size of the third emission area EAc (i.e., an aperture ratio) may be also increased.

In a plan view, the third connection pattern CNPc may surround a side, which faces the first emission area EAa and the second emission area EAb, among the sides of the third emission area EAc. For example, in a plan view, the third connection pattern CNPc may be disposed between the first emission area EAa and the third emission area EAc and between the second emission area EAb and the third emission area EAc. In other words, in a plan view, the third connection pattern CNPc, or one of the first connection pattern CNPa and the third connection pattern CNPc, may be disposed between the first emission area EAa and the third emission area EAc. In a plan view, the third connection pattern CNPc, or one of the second connection pattern CNPb and the third connection pattern CNPc, may be disposed between the second emission area EAb and the third emission area EAc.

The second electrode E2c of the third light emitting element LEDc may be connected to the third connection pattern CNPc. For example, the second electrode E2c of the third light emitting element LEDc may contact the third connection pattern CNPc. Accordingly, the third connection pattern CNPc may connect the third connection electrode CEc and the second electrode E2c of the third light emitting element LEDc to each other. As a result, the second electrode E2c of the third light emitting element LEDc may be connected to the third pixel driving circuit PCc through the third connection electrode CEc and the third connection pattern CNPc.

In an embodiment, in a plan view, a profile of an area where the second electrode E2c of the third light emitting element LEDc and the third connection pattern CNPc contact each other may be substantially the same as or similar to a profile of an edge of the third connection pattern CNPc. For example, in case that the third connection pattern CNPc partially surrounds the third emission area EAc in a plan view, the area where the second electrode E2c of the third light emitting element LEDc and the third connection pattern CNPc contact each other may partially surround the third emission area EAc in a plan view. For example, the second electrode E2c of the third light emitting element LEDc and the third connection pattern CNPc may contact each other at a position not overlapping the third emission area EAc in a plan view. Accordingly, the second electrode E2c of the third light emitting element LEDc and the third pixel driving circuit PCc may be connected to each other through the third connection pattern CNPc and the third connection electrode CEc without reducing the size of the third emission area EAc (i.e., an aperture ratio).

According to embodiments, the second electrodes E2a, E2b, and E2c may contact the first to third connection patterns CNPa, CNPb, and CNPc, respectively, at positions where the second electrodes E2a, E2b, and E2c do not overlap the first to third emission areas EAa, EAb, and EAc, respectively. Accordingly, the second electrodes E2a, E2b, and E2c may contact the first to third connection patterns CNPa, CNPb, and CNPc, respectively, without reducing the size of each of the first to third emission areas EAa, EAb, and EAc (i.e., an aperture ratio).

Accordingly, the second electrodes E2a, E2b, and E2c may be connected to the first to third pixel driving circuits PCa, PCb, and PCc through the first to third connection electrodes CEa, CEb, and CEc and the first to third connection patterns CNPa, CNPb, and CNPc, respectively. Accordingly, a limitation of the design of each of the first to third pixel driving circuits PCa, PCb, and PCc due to the positions, shapes, and sizes of the first to third emission areas EAa, EAb, and EAc may be reduced. For example, even if at least some of the first to third circuit connection portions CPa, CPb, and CPc overlap the first to third emission areas EAa, EAb, and EAc, the second electrodes E2a, E2b, and E2c may be readily connected to the first to third pixel driving circuits PCa, PCb, and PCc through the first to third connection electrodes CEa, CEb, and CEc and the first to third connection patterns CNPa, CNPb, and CNPc, respectively. Accordingly, shapes, arrangements, or the like, of the first to third pixel driving circuits PCa, PCb, and PCc may be designed independently of the positions, shapes, and sizes of the first to third emission areas EAa, EAb, and EAc. Accordingly, a degree of design freedom of each of the first to third pixel driving circuits PCa, PCb, and PCc may be improved.

In an embodiment, the first to third pixel driving circuits PCa, PCb, and PCc may be designed to be the same as each other regardless of the positions, shapes, and sizes of the first to third emission areas EAa, EAb, and EAc. As described above, the position of the first circuit connection portion CPa may correspond to the position of the first transistor TRI (see FIG. 6) of the first pixel driving circuit PCa, the position of the second circuit connection portion CPb may correspond to the position of the first transistor TR1 of the second pixel driving circuit PCb, and the position of the third circuit connection portion CPc may correspond to the position of the first transistor TR1 of the third pixel driving circuit PCc. Accordingly, in case that the first to third pixel driving circuits PCa, PCb, and PCc are formed to have substantially the same size and to be disposed in the first direction DR1, the position of the first circuit connection portion CPa, the position of the second circuit connection portion CPb, and the position of the third circuit connection portion CPc may be arranged in the first direction DR1.

According to embodiments, in a plan view, the first to third connection patterns CNPa, CNPb, and CNPc may partially surround the first to third emission areas EAa, EAb, and EAc, respectively. Accordingly, the limitation of the design of each of the first to third emission areas EAa, EAb, and EAc due to the first to third connection patterns CNPa, CNPb, and CNPc may be reduced. Accordingly, the degree of design freedom of each of the first to third emission areas EAa, EAb, and EAc may be improved, and the size of each of the first to third emission areas EAa, EAb, and EAc (i.e., an aperture ratio) may be also increased.

According to embodiments, in a plan view, even in case that the first to third connection patterns CNPa, CNPb, and CNPc partially surround the first to third emission areas EAa, EAb, and EAc, respectively, only one of corresponding connection patterns may be disposed between two emission areas facing each other. For example, one of the corresponding connection patterns may be disposed between two emission areas facing each other, and another one of the corresponding connection patterns may not be disposed between the two emission areas facing each other. Accordingly, while improving the degree of design freedom of each of the first to third emission areas EAa, EAb, and EAc, appropriate contact areas (or contact ratio) between the electrode layer E2 and the first to third connection patterns CNPa, CNPb, and CNPc may be maintained.

FIGS. 3 to 5 illustrate an embodiment in which the first to third emission areas EAa, EAb, and EAc are arranged in an S-stripe structure. However, the disclosure is not limited thereto, and even in case that the first to third emission areas EAa, EAb, and EAc are arranged in other type (e.g., PENTILE™ type, Diamond Pixel™ type, or the like), only one of corresponding connection patterns may be disposed between two emission areas facing each other.

As illustrated in FIG. 4, the shape or arrangement of each of the first to third connection electrodes CEa, CEb, and CEc and the arrangement relationship of the first to third connection electrodes CEa, CEb, and CEc may be the same for each first unit emission area UEA1. In an embodiment, the shape or arrangement of each of the first to third connection electrodes CEa, CEb, and CEc and the arrangement relationship of the first to third connection electrodes CEa, CEb, and CEc may be the same for each second unit emission area UEA2.

As illustrated in FIGS. 3 and 4, the shape or arrangement of each of the first to third connection patterns CNPa, CNPb, and CNPc and the arrangement relationship of the first to third connection patterns CNPa, CNPb, and CNPc may be the same for each first unit emission area UEA1. In an embodiment, the shape or arrangement of each of the first to third connection patterns CNPa, CNPb, and CNPc and the arrangement relationship of the first to third connection patterns CNPa, CNPb, and CNPc may be the same for each second unit emission area UEA2.

As described above, the display device DD may include the separator SPR.

The separator SPR may be disposed on the pixel defining layer PDL and the first to third connection patterns CNPa, CNPb, and CNPc. In an embodiment, the separator SPR may include an organic insulating material. For example, the separator SPR may include a photosensitive resin (e.g., a photoresist). However, the disclosure is not limited thereto.

The separator SPR may overlap the first to third connection patterns CNPa, CNPb, and CNPc in a plan view. For example, the separator SPR may cover a portion of each of the first to third connection patterns CNPa, CNPb, and CNPc and an area between adjacent connection patterns. For example, at least a portion of the separator SPR may extend along an edge of each of the first to third connection patterns CNPa, CNPb, and CNPc in a plan view. Accordingly, areas where the second electrodes E2a, E2b, and E2c and the first to third connection patterns CNPa, CNPb, and CNPc contact each other may be adjacent to or overlap the separator SPR in a plan view.

The electrode layer E2 may be separated (or disconnected) into the second electrodes E2a, E2b, and E2c by the separator SPR. For example, the second electrode E2a of the first light emitting element LEDa, the second electrode E2b of the second light emitting element LEDb, and the second electrode E2c of the third light emitting element LEDc may be electrically insulated from each other by the separator SPR.

The separator SPR may define first to third open areas OA1, OA2, and OA3 respectively corresponding to the second electrodes E2a, E2b, and E2c. For example, the separator SPR may have a mesh structure surrounding the second electrodes E2a, E2b, and E2c in a plan view. The second electrode E2a of the first light emitting element LEDa may be disposed in the first open area OA1 of the separator SPR, the second electrode E2b of the second light emitting element LEDb may be disposed in the second open area OA2 of the separator SPR, and the second electrode E2c of the third light emitting element LEDc may be disposed in the third open area OA3 of the separator SPR.

In an embodiment, a planar shape of the first open area OA1 and a planar shape of the second electrode E2a of the first light emitting element LEDa may be substantially the same, a planar shape of the second open area OA2 and a planar shape of the second electrode E2b of the second light emitting element LEDb may be substantially the same, and a planar shape of the third open area OA3 and a planar shape of the second electrode E2c of the third light emitting element LEDc may be substantially the same in a plan view.

The first to third open areas OA1, OA2, and OA3 of the separator SPR may correspond to the first to third connection patterns CNPa, CNPb, and CNPc, respectively. For example, in a plan view, the first connection pattern CNPa may overlap the first open area OA1, the second connection pattern CNPb may overlap the second open area OA2, and the third connection pattern CNPc may overlap the third open area OA3. The first open area OA1 may expose a portion of the first connection pattern CNPa, the second open area OA2 may expose a portion of the second connection pattern CNPb, and the third open area OA3 may expose a portion of the third connection pattern CNPc in a plan view.

Hereinafter, a cross-sectional structure of the display device DD will be described in more detail with reference to FIG. 6, focusing on the first emission area EAa. The following description of the cross-sectional structure of the display device DD may be substantially equally applied to all emission areas.

Further referring to FIG. 6, the display device DD may include the substrate SUB, a first bottom conductive layer BML1, a second bottom conductive layer BML2, the first transistor TR1, the second transistor TR2, the first capacitor CAP1, the second capacitor CAP2, the first connection electrode CEa, first to sixth insulating layers IL1, IL2, IL3, IL4, IL5, and IL6, the pixel defining layer PDL, the first connection pattern CNPa, the first light emitting element LEDa, the separator SPR, a first dummy layer DP1, a second dummy layer DP2, and an encapsulation layer ENC.

The first transistor TR1 may include a first active pattern AP1, a first gate electrode GE1, a first contact electrode SE1, and a second contact electrode DE1. The second transistor TR2 may include a second active pattern AP2, a second gate electrode GE2, a third contact electrode SE2, and a fourth contact electrode DE2. The first capacitor CAP1 may include a first capacitor electrode CPE1 and a second capacitor electrode CPE2. The second capacitor CAP2 may include the first capacitor electrode CPE1 and a third capacitor electrode CPE3. The first light emitting element LEDa may include the first electrode E1, the intermediate layer ML, and the second electrode E2a.

As described above, the first transistor TR1, the second transistor TR2, the first capacitor CAP1, and the second capacitor CAP2 may be components included in the first pixel driving circuit PCa.

The substrate SUB may serve as a base of the display device DD. In an embodiment, the substrate SUB may include glass, quartz, silicon, polymers, or the like. These may be used alone or in combination with each other. The substrate SUB may have a single-layer structure or a multi-layer structure in which multiple layers including different materials are stacked each other.

The first bottom conductive layer BML1, the second bottom conductive layer BML2, and the third capacitor electrode CPE3 may be disposed on the substrate SUB. The first bottom conductive layer BML1, the second bottom conductive layer BML2, and the third capacitor electrode CPE3 may include a conductive material such as a metal, an alloy, a conductive metal oxide, a conductive metal nitride, a transparent conductive oxide, or the like.

The first insulating layer IL1 may cover the first bottom conductive layer BML1, the second bottom conductive layer BML2, and the third capacitor electrode CPE3 and may be disposed on the substrate SUB. The first insulating layer IL1 may prevent or reduce metal atoms or impurities from diffusing from the substrate SUB to the first active pattern AP1 and/or the second active pattern AP2. The first insulating layer IL1 may include an insulating material. In an embodiment, the first insulating layer IL1 may include silicon oxide, silicon nitride, silicon oxynitride, or the like. These may be used alone or in combination with each other.

The first active pattern AP1 may be disposed on the first insulating layer IL1. In an embodiment, the first active pattern API may overlap the first bottom conductive layer BML1 in a plan view. The first active pattern AP1 may include an oxide semiconductor material, a silicon semiconductor material, and/or an organic semiconductor material. The first active pattern AP1 may include a first contact area S1, a second contact area D1, and a first channel area CH1 between the first contact area S1 and the second contact area D1. The first contact area S1 and the second contact area DI may have higher conductivity than the first channel area CH1.

The second active pattern AP2 may be disposed on the first insulating layer IL1. In an embodiment, the second active pattern AP2 may overlap the second bottom conductive layer BML2. The second active pattern AP2 may include an oxide semiconductor material, a silicon semiconductor material, and/or an organic semiconductor material. The second active pattern AP2 may include a third contact area S2, a fourth contact area D2, and a second channel area CH2 between the third contact area S2 and the fourth contact area D2. The third contact area S2 and the fourth contact area D2 may have higher conductivity than the second channel area CH2.

In an embodiment, the first active pattern API and the second active pattern AP2 may each include an oxide semiconductor material. For example, the first active pattern AP1 and the second active pattern AP2 may each include indium gallium zinc oxide (IGZO), zinc tin oxide (ZTO), indium tin zinc oxide (ITZO), or the like. These may be used alone or in combination with each other. However, the disclosure is not limited thereto, and the first active pattern AP1 and the second active pattern AP2 may include different materials. For example, one of the first active pattern AP1 and the second active pattern AP2 may include an oxide semiconductor material, and another one of the first active pattern AP1 and the second active pattern AP2 may include a silicon semiconductor material.

FIG. 6 illustrates that the first active pattern AP1 and the second active pattern AP2 are disposed on a same layer. However, the disclosure is not limited thereto, and the first active pattern AP1 and the second active pattern AP2 may be disposed on different layers.

The second insulating layer IL2 may cover the first active pattern AP1 and the second active pattern AP2 and may be disposed on the first insulating layer IL1. The second insulating layer IL2 may include an insulating material. In an embodiment, the second insulating layer IL2 may include silicon oxide, silicon nitride, silicon oxynitride, or the like. These may be used alone or in combination with each other.

The first gate electrode GE1 may be disposed on the second insulating layer IL2. The first gate electrode GE1 may overlap the first channel area CHI of the first active pattern AP1 in a plan view. The first gate electrode GE1 may include a conductive material such as a metal, an alloy, a conductive metal oxide, a conductive metal nitride, a transparent conductive oxide, or the like. Although not illustrated, in an embodiment, the first gate electrode GE1 may contact the first bottom conductive layer BML1.

The second gate electrode GE2 may be disposed on the second insulating layer IL2. The second gate electrode GE2 may overlap the second channel area CH2 of the second active pattern AP2 in a plan view. The second gate electrode GE2 may include a conductive material such as a metal, an alloy, a conductive metal oxide, a conductive metal nitride, a transparent conductive oxide, or the like. Although not illustrated, in an embodiment, the second gate electrode GE2 may contact the second bottom conductive layer BML2.

The first capacitor electrode CPE1 may be disposed on the second insulating layer IL2. The first capacitor electrode CPE1 may overlap the third capacitor electrode CPE3 in a plan view. The first capacitor electrode CPE1 and the third capacitor electrode CPE3 may form the second capacitor CAP2. The first capacitor electrode CPE1 may include a conductive material such as a metal, an alloy, a conductive metal oxide, a conductive metal nitride, a transparent conductive oxide, or the like.

The third insulating layer IL3 may cover the first gate electrode GE1, the second gate electrode GE2, and the first capacitor electrode CPE1 and may be disposed on the second insulating layer IL2. The third insulating layer IL3 may include an insulating material. In an embodiment, the third insulating layer IL3 may include silicon oxide, silicon nitride, silicon oxynitride, or the like. These may be used alone or in combination with each other.

The second capacitor electrode CPE2 may be disposed on the third insulating layer IL3. The second capacitor electrode CPE2 may overlap the first capacitor electrode CPE1 in a plan view. The first capacitor electrode CPE1 and the second capacitor electrode CPE2 may form the first capacitor CAP1. The second capacitor electrode CPE2 may include a conductive material such as a metal, an alloy, a conductive metal oxide, a conductive metal nitride, a transparent conductive oxide, or the like.

The fourth insulating layer IL4 may cover the second capacitor electrode CPE2 and may be disposed on the third insulating layer IL3. The fourth insulating layer IL4 may include an insulating material. In an embodiment, the fourth insulating layer IL4 may include silicon oxide, silicon nitride, silicon oxynitride, or the like. These may be used alone or in combination with each other.

The first to fourth contact electrodes SE1, DE1, SE2, and DE2 may be disposed on the fourth insulating layer IL4. The first contact electrode SE1 may contact the first contact area S1 of the first active pattern AP1, the second contact electrode DE1 may contact the second contact area D1 of the first active pattern AP1, the third contact electrode SE2 may contact the third contact area S2 of the second active pattern AP2, and the fourth contact electrode DE2 may contact the fourth contact area D2 of the second active pattern AP2. The first to fourth contact electrodes SE1, DE1, SE2, and DE2 may include a conductive material such as a metal, an alloy, a conductive metal oxide, a conductive metal nitride, a transparent conductive oxide, or the like.

In an embodiment, the first contact electrode SE1 may contact the first bottom conductive layer BML1, and the third contact electrode SE2 may contact the second bottom conductive layer BML2. However, the disclosure is not limited thereto. For example, in case that the first gate electrode GE1 contacts the first bottom conductive layer BML1, the first contact electrode SE1 may not contact the first bottom conductive layer BML1. In case that the second gate electrode GE2 contacts the second bottom conductive layer BML2, the third contact electrode SE2 may not contact the second bottom conductive layer BML2.

The fifth insulating layer IL5 may cover the first to fourth contact electrodes SE1, DE1, SE2, and DE2 and may be disposed on the fourth insulating layer IL4. The fifth insulating layer IL5 may include an insulating material. For example, the fifth insulating layer IL5 may include an organic insulating material. In an embodiment, the fifth insulating layer IL5 may include a photoresist, a polyacryl-based resin, a polyimide-based resin, a polyamide-based resin, a siloxane-based resin, an acrylic resin, an epoxy-based resin, or the like. These may be used alone or in combination with each other.

The first connection electrode CEa may be disposed on the fifth insulating layer IL5. As described above, the first connection electrode CEa may be connected to the first transistor TR1. For example, the first connection electrode CEa may contact the first transistor TR1 through a contact hole CNT that penetrates the fifth insulating layer IL5. Accordingly, the position of the first circuit connection portion CPa may correspond to a position of the contact hole CNT. The first connection electrode CEa may include a conductive material such as a metal, an alloy, a conductive metal oxide, a conductive metal nitride, a transparent conductive oxide, or the like. In an embodiment, the first connection electrode CEa may have a single-layer structure or a multi-layer structure in which multiple conductive layers are stacked each other.

As described above, the first transistor TR1 may be connected to the light emitting element through the connection electrode and the connection pattern. For example, in case that the first pixel driving circuit PCa is the pixel driving circuit PC of FIG. 2A, the first transistor TR1 may be the first transistor T1 of FIG. 2A. In case that the first pixel driving circuit PCa is the pixel driving circuit PC′ of FIG. 2B, the first transistor TR1 may be the fifth transistor T5 of FIG. 2B. In case that the first pixel driving circuit PCa is the pixel driving circuit PC″ of FIG. 2C, the first transistor TR1 may be the fifth transistor T5 of FIG. 2C.

The sixth insulating layer IL6 may partially cover the first connection electrode CEa and may be disposed on the fifth insulating layer IL5. For example, the sixth insulating layer IL6 may include a first sub-opening SOI that exposes at least a portion of the first connection electrode CEa. The sixth insulating layer IL6 may include an insulating material. For example, the sixth insulating layer IL6 may include an organic insulating material. In an embodiment, the sixth insulating layer IL6 may include a photoresist, a polyacryl-based resin, a polyimide-based resin, a polyamide-based resin, a siloxane-based resin, an acrylic resin, an epoxy-based resin, or the like. These may be used alone or in combination with each other.

The first electrode E1 may be disposed on the sixth insulating layer IL6. The first electrode E1 may include a conductive material such as a metal, an alloy, a conductive metal oxide, a conductive metal nitride, a transparent conductive oxide, or the like.

The pixel defining layer PDL may be disposed on the sixth insulating layer IL6 and the first electrode E1. The pixel defining layer PDL may include an insulating material. The pixel defining layer PDL may cover a portion of the first electrode E1. The pixel defining layer PDL may include a pixel opening that exposes at least a portion of the first electrode E1. The first emission area EAa may be defined by the pixel opening. In an embodiment, the pixel defining layer PDL may further include a second sub-opening SO2 corresponding to the first sub-opening SO1 of the sixth insulating layer IL6. The second sub-opening SO2 may overlap the first sub-opening SO1 in a plan view, and the first sub-opening SO1 and the second sub-opening SO2 may be spatially connected to each other. For example, the first sub-opening SO1 and the second sub-opening SO2 may be connected to form an opening OP, and the opening OP may expose at least a portion of the first connection electrode CEa.

The first connection pattern CNPa may be disposed on the first connection electrode CEa, the sixth insulating layer IL6, and the pixel defining layer PDL. As described above, the first connection pattern CNPa may be connected to the first connection electrode CEa. For example, the first connection pattern CNPa may be connected to the first connection electrode CEa through the opening OP that penetrates the sixth insulating layer IL6 and the pixel defining layer PDL. Accordingly, the position of the first light emitting connection portion CNa may correspond to a position of the opening OP. In an embodiment, the first connection pattern CNPa may include a transparent conductive oxide. However, the disclosure is not limited thereto, and the first connection pattern CNPa may include a conductive material such as a metal, an alloy, a conductive metal oxide, a conductive metal nitride, or the like. In an embodiment, the first connection pattern CNPa may have a single-layer structure or a multi- layer structure in which multiple conductive layers are stacked each other.

The separator SPR may be disposed on the pixel defining layer PDL and the first connection pattern CNPa. The separator SPR may partially overlap the first connection pattern CNPa in a plan view. For example, the separator SPR may cover a portion of the first connection pattern CNPa.

The separator SPR may have a shape in which a width of an upper portion is greater than a width of a lower portion in a horizontal direction. For example, a side surface of the separator SPR connecting an upper surface of the separator SPR and a lower surface of the separator SPR may be a reverse-tapered sloped surface. For example, a cross-sectional shape of at least a portion of the separator SPR may be a reverse trapezoid.

In an embodiment, as illustrated in FIG. 6, the side surface of the separator SPR may have multiple reverse-tapered sloped surfaces. For example, the separator SPR may have a double reverse-tapered structure. Accordingly, the electrode layer E2 may be more readily separated (or disconnected) by the separator SPR.

As illustrated in FIG. 6, a cross-sectional shape of at least a portion of the separator SPR may be asymmetric. As described above, in a plan view, the first to third connection patterns CNPa, CNPb, and CNPc may partially surround the first to third emission areas EAa, EAb, and EAc, respectively. Accordingly, a side surface of the at least a portion of the separator SPR may contact one of the first to third connection patterns CNPa, CNPb, and CNPc, and another side surface, which is opposite to the side surface, of the at least a portion of the separator SPR may contact the pixel defining layer PDL without contacting the first to third connection patterns CNPa, CNPb, and CNPc. Therefore, in a process for forming the separator SPR, a difference in degrees of inclination between the side surface and the another side surface may occur, due to a difference in characteristics (e.g., wettability with respect to a developer used in the patterning process for forming the separator SPR) between the pixel defining layer PDL and the first to third connection patterns CNPa, CNPb, and CNPc. For example, the separator SPR may have an undercut structure that is more etched in an area adjacent to the side surface than an area adjacent to the another side surface. Therefore, the cross-sectional shape of the at least a portion of the separator SPR may be asymmetric.

The intermediate layer ML may be disposed on the first electrode E1, the pixel defining layer PDL, and the first connection pattern CNPa. A portion of the intermediate layer ML may be disposed in the pixel opening of the pixel defining layer PDL. In an embodiment, the intermediate layer ML may include a first functional layer including an organic material, an emission layer disposed on the first functional layer and including an emission material, and a second functional layer disposed on the emission layer and including an organic material. For example, the first functional layer may include a hole injection layer, a hole transport layer, or the like, and the second functional layer may include an electron transport layer, an electron injection layer, or the like.

A shadow area where it is difficult to deposit the intermediate layer ML may exist around the separator SPR having reverse-tapered sloped surfaces. Accordingly, in the shadow area and/or around the shadow area, the intermediate layer ML may have a structure separated (or disconnected) by the separator SPR. For example, each of the first and second functional layers included in the intermediate layer ML may have a structure separated (or disconnected) by the separator SPR. Since the intermediate layer ML has a structure separated (or disconnected), the intermediate layer ML may not entirely cover the first connection pattern CNPa. For example, the intermediate layer ML may expose a portion of the first connection pattern CNPa at a position adjacent to or overlapping the separator SPR in a plan view. Accordingly, the second electrode E2a of the first light emitting element LEDa may contact the first connection pattern CNPa.

In an embodiment, the first dummy layer DP1 may be disposed on the separator SPR. The first dummy layer DP1 may be formed by the intermediate layer ML that is separated (or disconnected) by the separator SPR. For example, the first dummy layer DP1 and the intermediate layer ML may be formed in a same process. In another embodiment, the first dummy layer DP1 may be omitted.

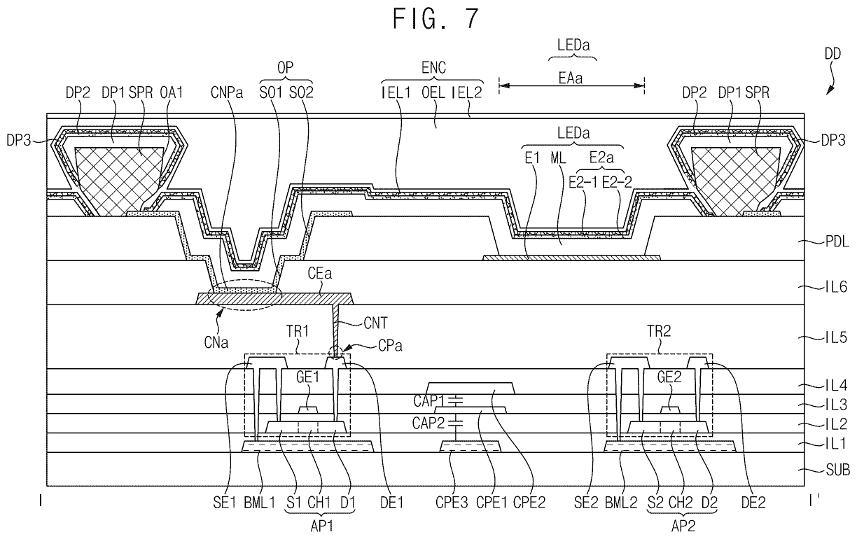

The electrode layer E2 (i.e., the second electrodes E2a, E2b, and E2c) may be disposed on the intermediate layer ML. The electrode layer E2 (i.e., the second electrodes E2a, E2b, and E2c) may include a conductive material such as a metal, an alloy, a conductive metal oxide, a conductive metal nitride, a transparent conductive oxide, or the like. In an embodiment, the electrode layer E2 (i.e., the second electrodes E2a, E2b, and E2c) may have a single-layer structure. However, the disclosure is not limited thereto, and the electrode layer E2 (i.e., the second electrodes E2a, E2b, and E2c) may have a multi-layer structure in which multiple conductive layers are stacked each other. This will be described in more detail below with reference to FIG. 7.

The shadow area where it is difficult to deposit the electrode layer E2 may exist around the separator SPR having reverse-tapered sloped surfaces. Accordingly, in the shadow area and/or around the shadow area, the electrode layer E2 may have a structure separated (or disconnected) by the separator SPR. For example, as illustrated in FIG. 5, the electrode layer E2 may be separated (or disconnected) into the second electrode E2a of the first light emitting element LEDa disposed in the first open area OA1 of the separator SPR, the second electrode E2b of the second light emitting element LEDb disposed in the second open area OA2 of the separator SPR, and the second electrode E2c of the third light emitting element LEDc disposed in the third open area OA3 of the separator SPR. For example, the second electrodes E2a, E2b, and E2c may be electrically insulated from each other.

As illustrated in FIG. 6, the second electrode E2a of the first light emitting element LEDa may be connected to the first connection pattern CNPa. For example, the second electrode E2a may contact the first connection pattern CNPa at a position adjacent to or overlapping the separator SPR in a plan view. For example, in case that a deposition angle of a deposition process for forming the electrode layer E2 is greater than a deposition angle of a deposition process for forming the intermediate layer ML, the electrode layer E2 (for example, the second electrode E2a) may be formed to cover a side portion of the separated (or disconnected) intermediate layer ML and to contact the first connection pattern CNPa. As a result, the second electrode E2a may be connected to the first transistor TR1 through the first connection electrode CEa and the first connection pattern CNPa.

In an embodiment, the second dummy layer DP2 may be disposed on the separator SPR. For example, the second dummy layer DP2 may be disposed on the first dummy layer DP1. The second dummy layer DP2 may be formed by the electrode layer E2 that is separated (or disconnected) by the separator SPR. For example, the second dummy layer DP2 and the electrode layer E2 may be formed in a same process. In another embodiment, the second dummy layer DP2 may be omitted.

The encapsulation layer ENC may be disposed on the electrode layer E2. The encapsulation layer ENC may entirely cover the electrode layer E2, the connection patterns CNPa, CNPb, and CNPc, the separator SPR, the first dummy layer DP1, and the second dummy layer DP2. In an embodiment, the encapsulation layer ENC may include a first inorganic encapsulation layer IEL1 including an inorganic insulating material, an organic encapsulation layer OEL disposed on the first inorganic encapsulation layer IEL1 and including an organic insulating material, and a second inorganic encapsulation layer IEL2 disposed on the organic encapsulation layer OEL and including an inorganic insulating material.

Although not illustrated, in an embodiment, a touch sensing layer may be disposed on the encapsulation layer ENC. For example, the touch sensing layer may include multiple touch electrode arrays for detecting a user's input in a capacitive manner, a touch pad portion, and multiple touch wires electrically connecting the touch pad portion and the touch electrode arrays. However, the disclosure is not limited thereto. In another embodiment, the touch sensing layer may be omitted.

According to embodiments, the display device DD may include the connection electrodes CEa, CEb, and CEc, the connection patterns CNPa, CNPb, and CNPc, and the separator SPR. Accordingly, the electrode layer E2 (e.g., the cathode) disposed on the first electrode E1 (e.g., the anode) may be readily connected to the pixel driving circuits PCa, PCb, and PCc. For example, the electrode layer E2 disposed on the first electrode E1 may be connected to the drain of the driving transistor (e.g., the first transistor T1 (or T1′) of FIGS. 2A to 2C) of each of the pixel driving circuits PCa, PCb, and PCc through the connection electrodes CEa, CEb, and CEc and the connection patterns CNPa, CNPb, and CNPc. Accordingly, even in case that the light emitting element deteriorates, the gate-source voltage (Vgs) of the driving transistor may not change. Accordingly, the range of change in the driving current due to the deterioration of the light emitting element may be reduced. Therefore, the after-image defect of the display device DD after an increase in the time of use may be reduced, and the lifespan of the display device DD may be improved.

According to embodiments, in a plan view, the first to third connection patterns CNPa, CNPb, and CNPc may partially surround the first to third emission areas EAa, EAb, and EAc, respectively. Accordingly, the limitation of the design of each of the first to third emission areas EAa, EAb, and EAc due to the first to third connection patterns CNPa, CNPb, and CNPc may be reduced. Accordingly, the degree of design freedom of each of the first to third emission areas EAa, EAb, and EAc may be improved, and the size of each of the first to third emission areas EAa, EAb, and EAc (i.e., an aperture ratio) may be increased. Therefore, display characteristics of the display device DD may be improved.

According to embodiments, in a plan view, even in case that the first to third connection patterns CNPa, CNPb, and CNPc partially surround the first to third emission areas EAa, EAb, and EAc, respectively, only one of corresponding connection patterns may be disposed between two emission areas facing each other. For example, one of the corresponding connection patterns may be disposed between the two emission areas facing each other, and another one of the corresponding connection patterns may not be disposed between the two emission areas facing each other. Accordingly, while improving the degree of design freedom of each of the first to third emission areas EAa, EAb, and EAc, appropriate contact areas (or contact ratio) between the electrode layer E2 and the first to third connection patterns CNPa, CNPb, and CNPc may be maintained.

FIG. 7 is a schematic cross-sectional view taken along line I-I′ of FIG. 5 according to an embodiment.

The display device DD according to an embodiment described below with reference to FIG. 7 may be substantially same as or similar to the display device DD described above with reference to FIGS. 3 to 6, except that the electrode layer E2 has a multi-layer structure. Therefore, repeated descriptions may be omitted.

Referring to FIGS. 5 and 7, in an embodiment, the electrode layer E2 (i.e., the second electrodes E2a, E2b, and E2c) may have a multi-layer structure in which multiple conductive layers are sequentially stacked. For example, the electrode layer E2 (i.e., the second electrodes E2a, E2b, and E2c) may include a first sub-electrode layer E2-1 and a second sub-electrode layer E2-2 disposed on the first sub-electrode layer E2-1.

In an embodiment, a third dummy layer DP3 may be disposed on the separator SPR. For example, the third dummy layer DP3 may be disposed on the second dummy layer DP2. The third dummy layer DP3 may be formed by the second sub-electrode layer E2-2 that is separated (or disconnected) by the separator SPR. For example, the third dummy layer DP3 and the second sub-electrode layer E2-2 may be formed in a same process. In another embodiment, the third dummy layer DP3 may be omitted.

In an embodiment, the first sub-electrode layer E2-1 may include a first conductive material. For example, the first sub-electrode layer E2-1 may include a metal, an alloy, a conductive metal nitride, or the like. For example, the first sub-electrode layer E2-1 may include Au, Ag, Al, Pt, Ni, Ti, Pd, Mg, Ca, Li, Cr, Ta, W, Cu, Mo, Sc, Nd, Ir, an alloy containing Al, an alloy containing Ag, an alloy containing Cu, an alloy containing Mo, AlN, WN, TiN, CrN, TaN, or the like. These may be used alone or in combination with each other.

In an embodiment, the second sub-electrode layer E2-2 may include a second conductive material different from the first conductive material. For example, the second sub-electrode layer E2-2 may include a transparent conductive oxide. For example, the second sub-electrode layer E2-2 may include IZO, IGZO, ITZO, ITO, IGO, ZnO, InO, SnO, GaO, AZO, or the like. These may be used alone or in combination with each other.

In an embodiment, in a plan view, sizes of areas where the second sub-electrode layer E2-2 overlaps the first to third connection patterns CNPa, CNPb, and CNPc may be greater than sizes of areas where the first sub-electrode layer E2-1 overlaps the first to third connection patterns CNPa, CNPb, and CNPc. For example, the second sub-electrode layer E2-2 may be closer to the separator SPR than the first sub-electrode layer E2-1. For example, a deposition angle of a deposition process for forming the second sub-electrode layer E2-2 may be greater than a deposition angle of a deposition process for forming the first sub-electrode layer E2-1. Accordingly, the second sub-electrode layer E2-2 may cover a side portion of the first sub-electrode layer E2-1 and may extend to a position closer to the separator SPR than the first sub-electrode layer E2-1. Accordingly, the sizes of the areas where the second sub-electrode layer E2-2 overlaps the first to third connection patterns CNPa, CNPb, and CNPc may be greater than the sizes of the areas where the first sub-electrode layer E2-1 overlaps the first to third connection patterns CNPa, CNPb, and CNPc.

For example, in a plan view, a size of an area where the second sub-electrode layer E2-2 overlaps the first connection pattern CNPa may be greater than a size of an area where the first sub-electrode layer E2-1 overlaps the first connection pattern CNPa. Similarly, in a plan view, a size of an area where the second sub-electrode layer E2-2 overlaps the second connection pattern CNPb may be greater than a size of an area where the first sub-electrode layer E2-1 overlaps the second connection pattern CNPb, and a size of an area where the second sub-electrode layer E2-2 overlaps the third connection pattern CNPc may be greater than a size of an area where the first sub-electrode layer E2-1 overlaps the third connection pattern CNPc.

Each of the first sub-electrode layer E2-1 and the second sub-electrode layer E2-2 may contact the first to third connection patterns CNPa, CNPb, and CNPc at positions adjacent to or overlapping the separator SPR in a plan view.

In an embodiment, in a plan view, sizes of areas where the second sub-electrode layer E2-2 contacts the first to third connection patterns CNPa, CNPb, and CNPc may be greater than sizes of areas where the first sub-electrode layer E2-1 contacts the first to third connection patterns CNPa, CNPb, and CNPc. For example, in a plan view, a size of an area where the second sub-electrode layer E2-2 contacts the first connection pattern CNPa may be greater than a size of an area where the first sub-electrode layer E2-1 contacts the first connection pattern CNPa. Similarly, in a plan view, a size of an area where the second sub- electrode layer E2-2 contacts the second connection pattern CNPb may be greater than a size of an area where the first sub-electrode layer E2-1 contacts the second connection pattern CNPb, and a size of an area where the second sub-electrode layer E2-2 contacts the third connection pattern CNPc may be greater than a size of an area where the first sub-electrode layer E2-1 contacts the third connection pattern CNPc.

As a result, according to embodiments in which the electrode layer E2 (i.e., the second electrodes E2a, E2b, and E2c) has the multi-layer structure in which the first sub-electrode layer E2-1 and the second sub-electrode layer E2-2 are sequentially stacked, the electrode layer E2 may be more readily connected to the connection patterns CNPa, CNPb, and CNPc. For example, contact areas (or contact ratio) between the electrode layer E2 and the connection patterns CNPa, CNPb, and CNPc may be further increased. Accordingly, the electrode layer E2 may be more readily connected to the pixel driving circuits PCa, PCb, and PCc through the connection patterns CNPa, CNPb, and CNPc.

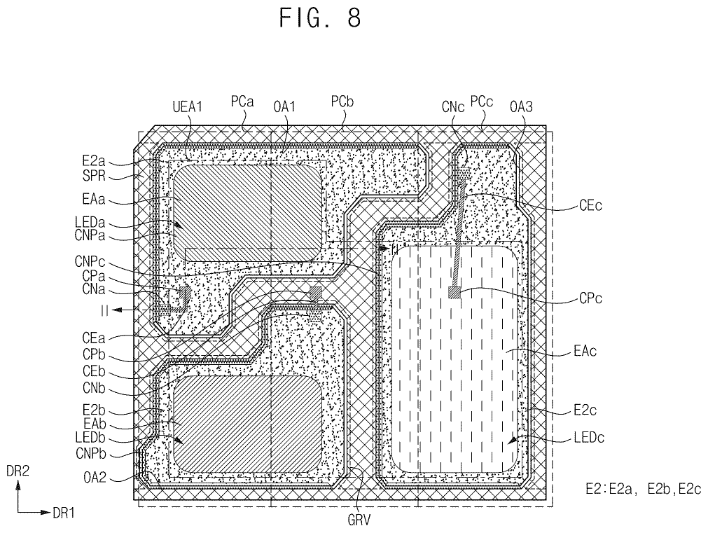

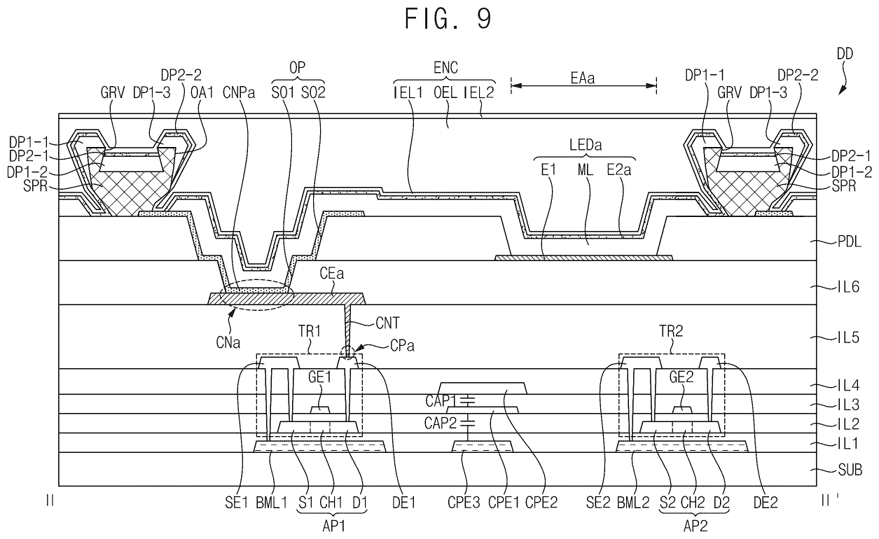

FIG. 8 is an enlarged view of one of unit emission areas of FIG. 4 according to an embodiment. FIG. 9 is a schematic cross-sectional view taken along line II-II′ of FIG. 8 according to an embodiment.

The display device DD according to an embodiment described below with reference to FIGS. 8 and 9 may be substantially same as or similar to the display device DD according to the embodiment described above with reference to FIGS. 3 to 6, except that the separator SPR includes a groove GRV. Therefore, repeated descriptions may be omitted.

Referring to FIGS. 8 and 9, in an embodiment, the separator SPR may include a groove GRV in which a portion of an upper surface of the separator SPR is recessed. For example, the groove GRV may be defined between the first to third emission areas EAa, EAb, and EAc in a plan view.

As described above, in a plan view, the first to third connection patterns CNPa, CNPb, and CNPc may partially surround the first to third emission areas EAa, EAb, and EAc, respectively. Accordingly, a side surface of the at least a portion of the separator SPR may contact one of the first to third connection patterns CNPa, CNPb, and CNPc, and another side surface, which is opposite to the side surface, of the at least a portion of the separator SPR may contact the pixel defining layer PDL without contacting the first to third connection patterns CNPa, CNPb, and CNPc. Therefore, in a process for forming the separator SPR, a difference in degrees of inclination between the side surface and the another side surface may occur, due to a difference in characteristics (e.g., wettability with respect to a developer used in the patterning process for forming the separator SPR) between the pixel defining layer PDL and the first to third connection patterns CNPa, CNPb, and CNPc. For example, the separator SPR may have an undercut structure that is more etched adjacent to the side surface than adjacent to the another side surface. In case that a deposition angle of a deposition process for forming the electrode layer E2 is greater than a critical angle, the electrode layer E2 may not be separated (or disconnected) by the separator SPR adjacent to the another side surface of the separator SPR. For example, the electrode layer E2 may extend along the another side surface of the separator SPR to the upper surface of the separator SPR.

Even in case that the electrode layer E2 extends along the another side surface of the separator SPR to the upper surface of the separator SPR, the electrode layer E2 may not extend to the side surface of the separator SPR and may extend only to a point of the upper surface of the separator SPR by being separated (or disconnected) by the groove GRV. For example, the electrode layer E2 may be separated from a second-first dummy layer DP2-1, which is disposed in the groove GRV, by the groove GRV. In other words, the second-first dummy layer DP2-1 may be formed by the electrode layer E2 that is separated (or disconnected) by the groove GRV of the separator SPR. For example, the second-first dummy layer DP2-1 and the electrode layer E2 may be formed in a same process.

As a result, even in case that the electrode layer E2 is not separated (or disconnected) around at least a portion of the separator SPR because the first to third connection patterns CNPa, CNPb, and CNPc respectively partially surround the first to third emission areas EAa, EAb, EAc in a plan view, the separation (or disconnection) of the electrode layer E2 by the separator SPR may sufficiently occur by the groove GRV defined in the separator SPR. For example, as the groove GRV is defined in the separator SPR, it may be possible to further increase the deposition angle of the deposition process for forming the electrode layer E2, and thus, sizes of areas where the electrode layer E2 contacts the connection patterns CNPa, CNPb, and CNPc may be increased. Accordingly, contact areas (or contact ratio) between the electrode layer E2 and the connection patterns CNPa, CNPb, and CNPc may be further increased. Therefore, the electrode layer E2 may be more readily connected to the pixel driving circuits PCa, PCb, and PCc through the connection patterns CNPa, CNPb, and CNPc.

In the embodiment in which the groove GRV is defined in the separator SPR, a first-first dummy layer DP1-1, a first-second dummy layer DP1-2, a first-third dummy layer DP1- 3, the second-first dummy layer DP2-1, and a second-second dummy layer DP2-2 may be disposed on the separator SPR, and the first dummy layer DP1 and the second dummy layer DP2 described above with reference to FIG. 6 may be omitted.

The first-first dummy layer DP1-1, the first-second dummy layer DP1-2, and the first-third dummy layer DP1-3 may be disposed on the separator SPR. The first-first dummy layer DP1-1, the first-second dummy layer DP1-2, and the first-third dummy layer DP1-3 may be formed by the intermediate layer ML that is separated (or disconnected) by the separator SPR. For example, the first-first dummy layer DP1-1, the first-second dummy layer DP1-2, the first-third dummy layer DP1-3, and the intermediate layer ML may be formed in a same process. For example, the first-first dummy layer DP1-1, the first-second dummy layer DP1-2, and the first-third dummy layer DP1-3 may be formed by the intermediate layer ML that is separated (or disconnected) due to the undercut structure of the separator SPR and the groove GRV of the separator SPR. The first-second dummy layer DP1-2 may be disposed in the groove GRV.

The second-first dummy layer DP2-1 and the second-second dummy layer DP2-2 may be disposed on the first-second dummy layer DP1-2 and the first-third dummy layer DP1-3. For example, the second-first dummy layer DP2-1 may be disposed on the first-second dummy layer DP1-2, and the second-second dummy layer DP2-2 may be disposed on the first-third dummy layer DP1-3. The second-first dummy layer DP2-1 and the second-second dummy layer DP2-2 may be formed by the electrode layer E2 that is separated (or disconnected) due to the undercut structure of the separator SPR and the groove GRV of the separator SPR. For example, the second-first dummy layer DP2-1, the second-second dummy layer DP2-2, and the electrode layer E2 may be formed in a same process. For example, the second-first dummy layer DP2-1 may be separated (or disconnected) from the electrode layer E2 by the groove GRV defined in the separator SPR. The second-first dummy layer DP2-1 may be disposed in the groove GRV.

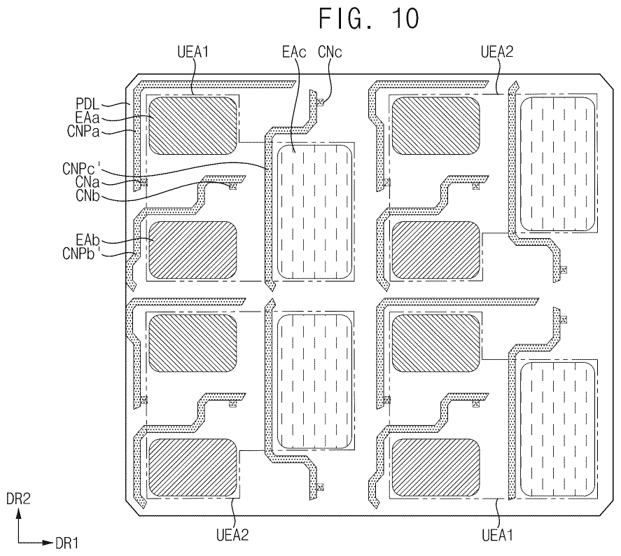

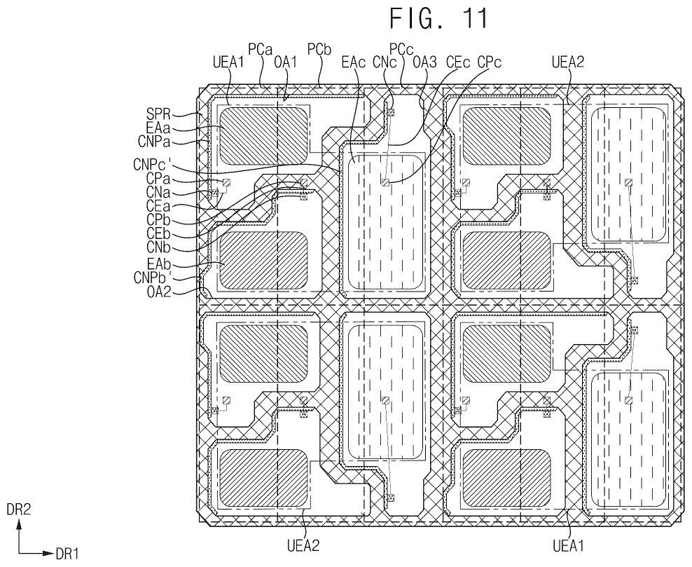

FIGS. 10 and 11 are plan views schematically illustrating a portion of the display device of FIGS. 1A and 1B according to an embodiment.

For example, FIG. 10 may correspond to FIG. 3, and FIG. 11 may correspond to FIG. 4. For example, similar to FIGS. 3 and 4, FIGS. 10 and 11 schematically illustrate an area in which four unit emission areas UEA1 and UEA2 forming a matrix of two rows and two columns are arranged.

The display device DD according to an embodiment described below with reference to FIGS. 10 and 11 may be substantially same as or similar to the display device DD described above with reference to FIGS. 3 to 6, except for a second connection pattern CNPb′ and a third connection pattern CNPc′. Therefore, repeated descriptions may be omitted.

Referring to FIGS. 10 and 11, in an embodiment, the display device DD may include a second connection pattern CNPb′ and a third connection pattern CNPc′.

The second connection pattern CNPb′ may be substantially the same as or similar to the second connection pattern CNPb described above with reference to FIGS. 3 to 6, except for a shape that partially surrounds the second emission area EAb in a plan view. The third connection pattern CNPc′ may be substantially the same as or similar to the third connection pattern CNPc described above with reference to FIGS. 3 to 6, except for a shape that partially surrounds the third emission area EAc in a plan view. Therefore, repeated descriptions may be omitted.

In an embodiment, compared to the embodiment of the display device DD described above with reference to FIGS. 3 to 6, the first to third connection patterns CNPa, CNPb′, and CNPc′ may surround the first to third emission areas EAa, EAb, and EAc less in a plan view. Accordingly, the limitation of the design of each of the first to third emission areas EAa, EAb, and EAc due to the first to third connection patterns CNPa, CNPb′, and CNPc′ may be further reduced. Accordingly, the degree of design freedom of each of the first to third emission areas EAa, EAb, and EAc may be further improved, and the size of each of the first to third emission areas EAa, EAb, and EAc (i.e., an aperture ratio) may be further increased.

In an embodiment, in the first unit emission area UEA1 and the second unit emission area UEA2 adjacent to each other, in a plan view, only one or none of the first to third connection patterns CNPa, CNPb′, and CNPc′ may be disposed between an emission area of the first unit emission area UEA1 and an emission area, which faces the emission area of the first unit emission area UEA1, of the second unit emission area UEA2

For example, in a plan view, in the first unit emission area UEA1 (e.g., the upper left first unit emission area UEA1 of FIG. 10), the second connection pattern CNPb′ may not surround a side, which faces the second unit emission area UEA2 adjacent in a direction opposite to the second direction DR2, among sides of the second emission area EAb. In a plan view, in the first unit emission area UEA1 (e.g., the upper left first unit emission area UEA1 of FIG. 10), the third connection pattern CNPc′ may not surround a side, which faces the second unit emission area UEA2 adjacent in the direction opposite to the second direction DR2, among sides of the third emission area EAc. In a plan view, in the second unit emission area UEA2 (e.g., the upper right second unit emission area UEA2 of FIG. 10), the second connection pattern CNPb' may not surround a side, which faces the first unit emission area UEA1 adjacent in the direction opposite to the second direction DR2, among sides of the second emission area EAb. In a plan view, in the second unit emission area UEA2 (e.g., the lower left second unit emission area UEA2 of FIG. 10), the third connection pattern CNPc′ may not surround a side, which faces the first unit emission area UEA1 adjacent in the second direction DR2, among sides of the third emission area EAc. However, the disclosure is not limited thereto.

FIGS. 10 and 11 schematically illustrate an embodiment in which the first to third emission areas EAa, EAb, and EAc are disposed in an S-stripe structure and the first unit emission areas UEA1 and the second unit emission areas UEA2 are alternately disposed in the first direction DR1 and the second direction DR2. However, the disclosure is not limited thereto, and even in case that the first to third emission areas EAa, EAb, and EAc are disposed in other type (e.g., PENTILE™ type, Diamond Pixel™ type, or the like) and/or the number of different unit emission areas included in the display device DD or the arrangement of the unit emission areas is changed, in the adjacent unit emission areas, only one or none of the corresponding connection patterns may be disposed between an emission area of one of the adjacent unit emission areas and another emission area, which faces the emission area of the one of adjacent unit emission areas, of another of the adjacent unit emission areas.

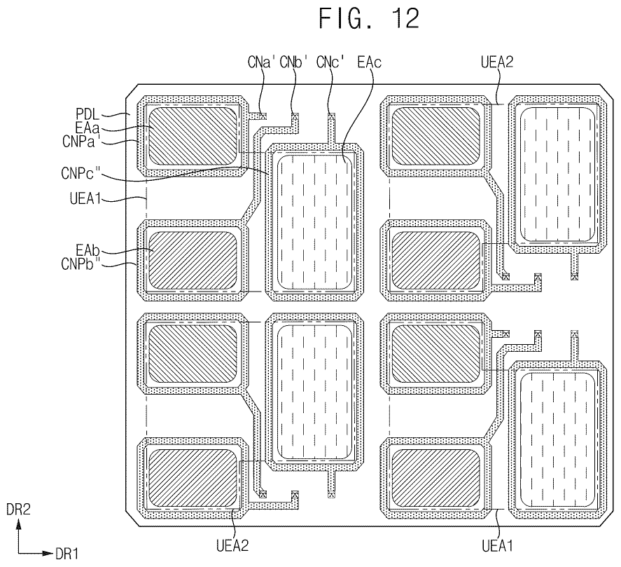

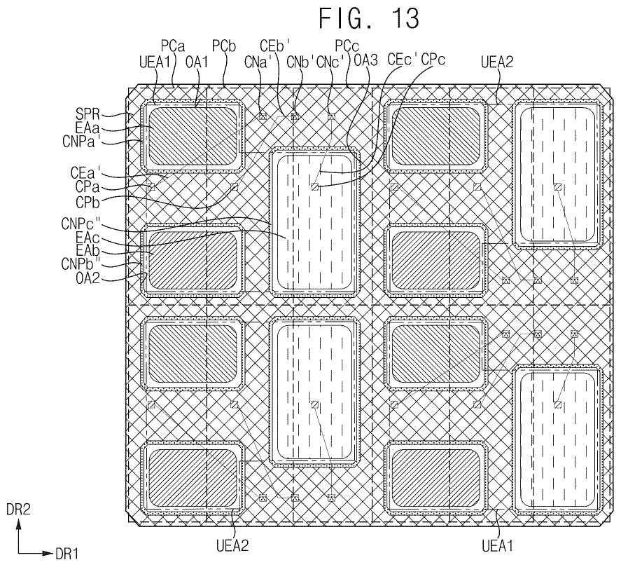

FIGS. 12 and 13 are plan views schematically illustrating a portion of the display device of FIGS. 1A and 1B according to an embodiment.

For example, FIG. 12 may correspond to FIG. 3, and FIG. 13 may correspond to FIG. 4. For example, similar to FIGS. 3 and 4, FIGS. 12 and 13 schematically illustrate an area in which four unit emission areas UEA1 and UEA2 forming a matrix of two rows and two columns are arranged.

The display device DD according to an embodiment described below with reference to FIGS. 12 and 13 may be substantially same as or similar to the display device DD described above with reference to FIGS. 3 to 6, except for first to third connection patterns CNPa′, CNPb″, and CNPc″, first to third connection electrodes CEa′, CEb′, and CEc′, and first to third light emitting connection portions CNa′, CNb′, and CNc′. Therefore, repeated descriptions may be omitted.

Referring to FIGS. 12 and 13, in an embodiment, the display device DD may include first to third connection patterns CNPa, CNPb″, and CNPc″ and first to third connection electrodes CEa′, CEb′, and CEc′.

The first to third connection patterns CNPa′, CNPb″, and CNPc″ may be respectively substantially the same as or similar to the first to third connection patterns CNPa, CNPb, and CNPc described above with reference to FIGS. 3 to 6, except for planar shapes. The first to third connection electrodes CEa′, CEb′, and CEc′ may be respectively substantially the same as or similar to the first to third connection electrodes CEa, CEb, and CEc described above with reference to FIGS. 3 to 6, except for planar shapes. Therefore, repeated descriptions may be omitted.

The first connection pattern CNPa′ may be connected to a first light emitting connection portion CNa′ of the first connection electrode CEa′. As described above, a position of the first light emitting connection portion CNa may correspond to a position of an opening in which a first sub-opening, which exposes the first connection electrode CEa′, of the sixth insulating layer IL6 (see FIG. 6) and a second sub-opening of the pixel defining layer PDL are connected to each other. In an embodiment, the first light emitting connection portion CNa′ may overlap the separator SPR in a plan view. For example, the opening may overlap the separator SPR in a plan view. In other words, the first sub-opening and the second sub-opening may overlap the separator SPR in a plan view. For example, the first light emitting connection portion CNa may be located outside the first open area OA1 of the separator SPR in a plan view.

The second connection pattern CNPb″ may be connected to a second light emitting connection portion CNb′ of the second connection electrode CEb. As described above, a position of the second light emitting connection portion CNb′ may correspond to a position of an opening in which a first sub-opening, which exposes the second connection electrode CEb′, of the sixth insulating layer IL6 (see FIG. 6) and a second sub-opening of the pixel defining layer PDL are connected to each other. In an embodiment, the second light emitting connection portion CNb′ may overlap the separator SPR in a plan view. For example, the opening may overlap the separator SPR in a plan view. In other words, the first sub-opening and the second sub-opening may overlap the separator SPR in a plan view. For example, the second light emitting connection portion CNb may be located outside the second open area OA2 of the separator SPR in a plan view.

The third connection pattern CNPc″ may be connected to a third light emitting connection portion CNc′ of the third connection electrode CEc′. As described above, a position of the third light emitting connection portion CNc′ may correspond to a position of an opening in which a first sub-opening, which exposes the third connection electrode CEc′, of the sixth insulating layer IL6 (see FIG. 6) and a second sub-opening of the pixel defining layer PDL are connected to each other. In an embodiment, the third light emitting connection portion CNc′ may overlap the separator SPR in a plan view. For example, the opening may overlap the separator SPR in a plan view. In other words, the first sub-opening and the second sub-opening may overlap the separator SPR in a plan view. For example, the third light emitting connection portion CNc′ may be located outside the third open area OA3 of the separator SPR in a plan view.

According to embodiments of FIGS. 12 and 13, in a plan view, the first to third light emitting connecting portions CNa′, CNb′, and CNc′ may overlap the separator SPR depending on the shapes (or arrangements) of the first to third connection electrodes CEa′, CEb′, and CEc′ and the first to third connection patterns CNPa′, CNPb″, and CNPc″. For example, in a plan view, each of the first to third light emitting connection portions CNa′, CNb′, and CNc′ may be located outside the first to third open areas OA1, OA2, and OA3. Accordingly, the limitation of the design of each of the first to third emission areas EAa, EAb, and EAc due to the first to third light emitting connection portions CNa′, CNb′, and CNc′ may be reduced. Accordingly, the degree of design freedom of each of the first to third emission areas EAa, EAb, and EAc may be improved, and the size of each of the first to third emission areas EAa, EAb, and EAc (i.e., an aperture ratio) may be further increased.

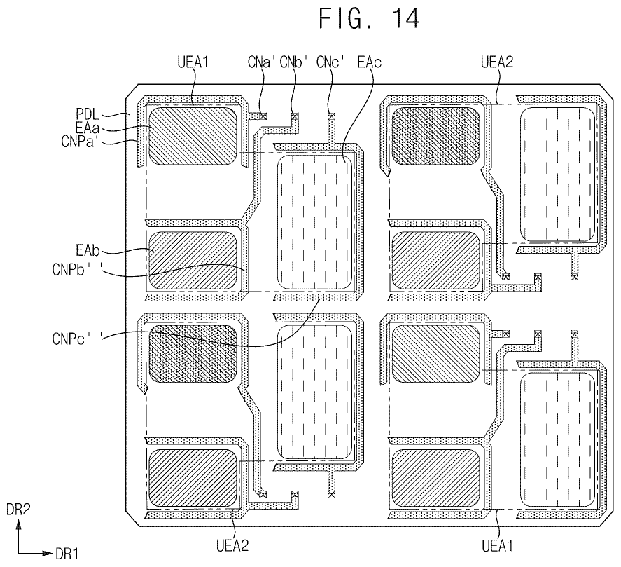

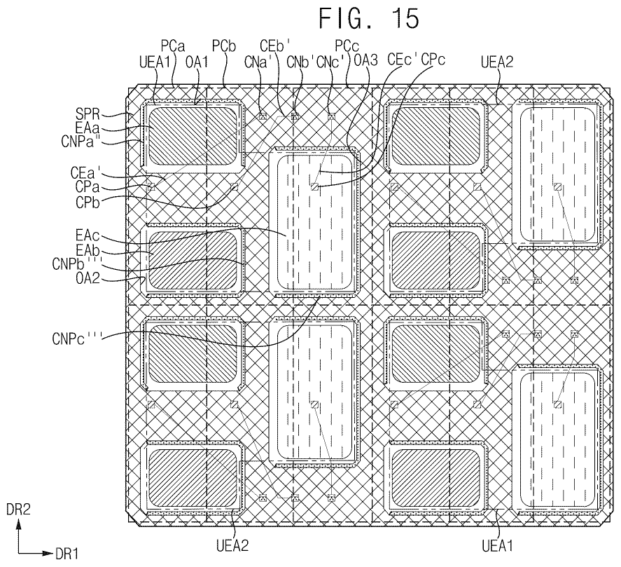

In an embodiment, in case that the first to third light emitting connecting portions CNa′, CNb′, and CNc′ overlap the separator SPR in a plan view, the first to third connection patterns CNPa′, CNPb″, and CNPc″ may entirely surround the first to third emission areas EAa, EAb, and EAc in a plan view, respectively. For example, in a plan view, the first connection pattern CNPa′ may entirely surround the first emission area EAa, the second connection pattern CNPb″ may entirely surround the second emission area EAb, and the third connection pattern CNPc′ may entirely surround the third emission area EAc. However, the disclosure is not limited thereto, and even in case that the first to third light emitting connecting portions CNa, CNb′, and CNc′ overlap the separator SPR in a plan view, the first to third connection patterns CNPa′, CNPb″, and CNPc″ may partially surround the first to third emission areas EAa, EAb, and EAc in a plan view, respectively. This will be described in more detail below with reference to FIGS. 14 and 15.

FIGS. 14 and 15 are plan views schematically illustrating a portion of the display device of FIGS. 1A and 1B according to an embodiment.

For example, FIG. 14 may correspond to FIG. 3, and FIG. 15 may correspond to FIG. 4. For example, similar to FIGS. 3 and 4, FIGS. 14 and 15 schematically illustrate an area in which four unit emission areas UEA1 and UEA2 forming a matrix of two rows and two columns are arranged.

The display device DD according to an embodiment described below with reference to FIGS. 14 and 15 may be substantially same as or similar to the display device DD described above with reference to FIGS. 12 and 13, except for first to third connection patterns CNPa″, CNPb″, and CNPc″. Therefore, repeated descriptions may be omitted.

Referring to FIGS. 14 and 15, in an embodiment, the display device DD may include first to third connection patterns CNPa″, CNPb′″, and CNPc′″.

The first to third connection patterns CNPa″, CNPb′″, and CNPc″ may be respectively substantially the same as or similar to the first to third connection patterns CNPa′, CNPb″, and CNPc″ described above with reference to FIGS. 12 and 13, except that the first to third connection patterns CNPa″, CNPb″, and CNPc″ may partially surround the first to third emission areas EAa, EAb, and EAc in a plan view, respectively. Therefore, repeated descriptions may be omitted.

In an embodiment, the first connection pattern CNPa″ may partially surround the first emission area EAa in a plan view. For example, in a plan view, the first connection pattern CNPa″ may not surround a side, which faces the second emission area EAb, among sides of the first emission area EAa. For example, in a plan view, the first connection pattern CNPa″ may not be disposed between the first emission area EAa and the second emission area EAb.

In an embodiment, the second connection pattern CNPb′″ may partially surround the second emission area EAb in a plan view. For example, in a plan view, the second connection pattern CNPb″ may not surround at least one of sides of the second emission area EAb.

In a plan view, the second connection pattern CNPb″ may surround a side, which faces the first emission area EAa, among the sides of the second emission area EAb. For example, in a plan view, the second connection pattern CNPb″ may be disposed between the first emission area EAa and the second emission area EAb. In other words, in a plan view, the second connection pattern CNPb′″, or one of the first connection pattern CNPa″ and the second connection pattern CNPb′″, may be disposed between the first emission area EAa and the second emission area EAb.

In an embodiment, the third connection pattern CNPc′″ may partially surround the third emission area EAc in a plan view. For example, in a plan view, the third connection pattern CNPc″ may not surround a side, which faces the first emission area EAa and the second emission area EAb, among sides of the third emission area EAc. For example, in a plan view, the third connection pattern CNPc″ may not be disposed between the first emission area EAa and the third emission area EAc and between the second emission area EAb and the third emission area EAc.

In a plan view, the first connection pattern CNPa″ may surround a side, which faces the third emission area EAc, among the sides of the first emission area EAa. For example, in a plan view, the first connection pattern CNPa″ may be disposed between the first emission area EAa and the third emission area EAc. In other words, in a plan view, the first connection pattern CNPa″, or one of the first connection pattern CNPa″ and the third connection pattern CNPc″′, may be disposed between the first emission area EAa and the third emission area EAc.

In a plan view, the second connection pattern CNPb″ may surround a side, which faces the third emission area EAc, among the sides of the second emission area EAb. For example, in a plan view, the second connection pattern CNPb″ may be disposed between the second emission area EAb and the third emission area EAc. In other words, in a plan view, the second connection pattern CNPb″′, or one of the second connection pattern CNPb″′ and the third connection pattern CNPc′″, may be disposed between the second emission area EAb and the third emission area EAc.

As described above, in a plan view, the first to third connection patterns CNPa″, CNPb′″, and CNPc′″ may partially surround the first to third emission areas EAa, EAb, and EAc, respectively, and thus, the limitation of the design of each of the first to third emission areas EAa, EAb, and EAc due to the first to third connection patterns CNPa″, CNPb′″, and CNPc′″ may be reduced. Accordingly, the degree of design freedom of each of the first to third emission areas EAa, EAb, and EAc may be improved, and the size of each of the first to third emission areas EAa, EAb, and EAc (i.e., an aperture ratio) may be further increased. Therefore, display characteristics of the display device DD may be improved.

According to embodiments, in a plan view, even in case that the first to third connection patterns CNPa′, CNPb′, and CNPc′″ partially surround the first to third emission areas EAa, EAb, and EAc, respectively, only one of corresponding connection patterns may be disposed between two emission areas facing each other. For example, one of the corresponding connection patterns may be disposed between the two emission areas facing each other, and another one of the corresponding connection patterns may not be disposed between the two emission areas facing each other. Accordingly, while improving the degree of design freedom of each of the first to third emission areas EAa, EAb, and EAc, appropriate contact areas (or contact ratio) between the electrode layer E2 and the first to third connection patterns CNPa′, CNPb″′, and CNPc′″ may be maintained.

FIGS. 14 and 15 schematically illustrate that the first to third connection patterns CNPa″, CNPb″, and CNPc″ partially surround the first to third emission areas EAa, EAb, and EAc, respectively, but the disclosure is not limited thereto. For example, as long as the first to third light emitting connection portions CNa′, CNb′, and CNc′ overlap the separator SPR in a plan view, detailed shapes in which the first to third connection patterns CNPa″, CNPb′″, and CNPc′″ partially surround the first to third emission areas EAa, EAb, and EAc, respectively, may be changed according to embodiments. For example, the detailed shapes in which the first to third connection patterns CNPa″, CNPb′″, and CNPc′″ partially surround the first to third emission areas EAa, EAb, and EAc, respectively, may be variously changed depending on the arrangement type (e.g., S-stripe type, PENTILE™ type, Diamond Pixel™ type, or the like) of the emission areas EAa, EAb, and EAc and/or the number or arrangement relationship of the unit emission areas UEA1 and UEA2.

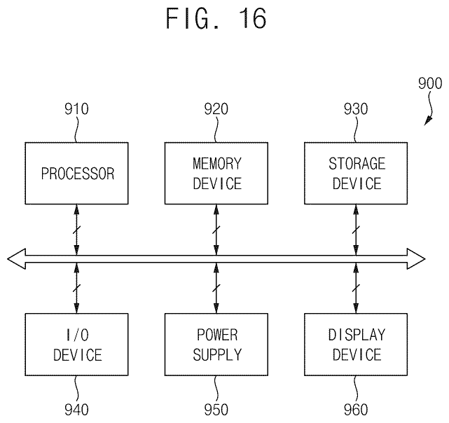

FIG. 16 is a block diagram illustrating an electronic device according to an embodiment.

Referring to FIG. 16, in an embodiment, an electronic device 900 may include a processor 910, a memory device 920, a storage device 930, an input/output (“I/O”) device 940, a power supply 950, and a display device 960. Here, the display device 960 may correspond to the display device DD (or DDa) of FIGS. 1A and 1B. The electronic device 900 may further include a plurality of ports for communicating with a video card, a sound card, a memory card, a universal serial bus (“USB”) device, or the like. In an embodiment, the electronic device 900 may be implemented as a television. In another embodiment, the electronic device 900 may be implemented as a smart phone. However, embodiments are not limited thereto, in another embodiment, the electronic device 900 may be implemented as a cellular phone, a video phone, a smart pad, a smart watch, a tablet personal computer (“PC”), a car navigation system, a computer monitor, a laptop, a head disposed (e.g., mounted) display (“HMD”), or the like.

The processor 910 may perform various computing functions. In an embodiment, the processor 910 may be a microprocessor, a central processing unit (“CPU”), an application processor (“AP”), or the like. The processor 910 may be coupled to other components via an address bus, a control bus, a data bus, or the like. In an embodiment, the processor 910 may be coupled to an extended bus such as a peripheral component interconnection (“PCI”) bus.

The memory device 920 may store data for operations of the electronic device 900. In an embodiment, the memory device 920 may include at least one non-volatile memory device such as an erasable programmable read-only memory (“EPROM”) device, an electrically erasable programmable read-only memory (“EEPROM”) device, a flash memory device, a phase change random access memory (“PRAM”) device, a resistance random access memory (“RRAM”) device, a nano floating gate memory (“NFGM”) device, a polymer random access memory (“PoRAM”) device, a magnetic random access memory (“MRAM”) device, a ferroelectric random access memory (“FRAM”) device, or the like, and/or at least one volatile memory device such as a dynamic random access memory (“DRAM”) device, a static random access memory (“SRAM”) device, a mobile DRAM device, or the like.

In an embodiment, the storage device 930 may include a solid state drive (“SSD”) device, a hard disk drive (“HDD”) device, a CD-ROM device, or the like. In an embodiment, the I/O device 940 may include an input device such as a keyboard, a keypad, a mouse device, a touchpad, a touch-screen, or the like, and an output device such as a printer, a speaker, or the like.

The power supply 950 may provide power for operations of the electronic device 900. The power supply 950 may provide power to the display device 960. The display device 960 may be coupled to other components via the buses or other communication links. In an embodiment, the display device 960 may be included in the I/O device 940.

The above description is an example of technical features of the disclosure, and those skilled in the art to which the disclosure pertains will be able to make various modifications and variations. Therefore, the embodiments of the disclosure described above may be implemented separately or in combination with each other.

Therefore, the embodiments disclosed in the disclosure are not intended to limit the technical spirit of the disclosure, but to describe the technical spirit of the disclosure, and the scope of the technical spirit of the disclosure is not limited by these embodiments. The protection scope of the disclosure should be interpreted by the following claims, and it should be interpreted that all technical spirits within the equivalent scope are included in the scope of the disclosure.

What is claimed is:

1. A display device comprising:
a first pixel driving circuit and a second pixel driving circuit each including a transistor;
a first connection electrode electrically connected to the first pixel driving circuit;
a second connection electrode electrically connected to the second pixel driving circuit;
a first electrode disposed on the first connection electrode and the second connection electrode;
a pixel defining layer covering at least a portion of the first electrode and defining a first emission area and a second emission area adjacent to each other;
a first connection pattern electrically connected to the first connection electrode and partially surrounding the first emission area in a plan view;
a second connection pattern electrically connected to the second connection electrode and partially surrounding the second emission area in the plan view;
a separator disposed on the pixel defining layer, the first connection pattern, and the second connection pattern and covering at least a portion of each of the first connection pattern and the second connection pattern; and
an electrode layer disposed on the first electrode and electrically connected to each of the first connection pattern and the second connection pattern.

2. The display device of claim 1, wherein, in the plan view, one of the first connection pattern and the second connection pattern is disposed between the first emission area and the second emission area.

3. The display device of claim 1, wherein a cross-sectional shape of a portion of the separator is asymmetrical.

4. The display device of claim 3, wherein
a side surface of the portion of the separator contacts one of the first connection pattern and the second connection pattern, and
another side surface, which is opposite to the side surface, of the portion of the separator contacts the pixel defining layer and does not contact the first connection pattern nor the second connection pattern.

5. The display device of claim 1, wherein the first connection pattern and the second connection pattern are electrically insulated from each other.

6. The display device of claim 1, wherein
the separator defines a first open area exposing a portion of the first connection pattern and a second open area exposing a portion of the second connection pattern in the plan view, and
the electrode layer is separated into an electrode disposed in the first open area and another electrode disposed in the second open area by the separator.

7. The display device of claim 6, wherein
the electrode disposed in the first open area contacts the first connection pattern at a position adjacent to or overlapping the separator in the plan view, and
the another electrode disposed in the second open area contacts the second connection pattern at another position adjacent to or overlapping the separator in the plan view.

8. The display device of claim 6, wherein
the electrode disposed in the first open area is electrically connected to the first pixel driving circuit through the first connection electrode and the first connection pattern, and
the another electrode disposed in the second open area is electrically connected to the second pixel driving circuit through the second connection electrode and the second connection pattern.

9. The display device of claim 6, wherein the electrode disposed in the first open area and the another electrode disposed in the second open area are electrically insulated from each other.

10. The display device of claim 1, wherein
the electrode layer includes:
a first sub-electrode layer including a first conductive material; and
a second sub-electrode layer disposed on the first sub-electrode layer and including a second conductive material, and
the first conductive material and the second conductive material are different from each other.

11. The display device of claim 10, wherein
the first conductive material is a metal, and
the second conductive material is a transparent conductive oxide.

12. The display device of claim 10, wherein
the first sub-electrode layer contacts each of the first connection pattern and the second connection pattern at a position adjacent to or overlapping the separator in the plan view, and
the second sub-electrode layer contacts each of the first connection pattern and the second connection pattern at the position adjacent to or overlapping the separator in the plan view.

13. The display device of claim 12, wherein,
in the plan view, a size of an area where the second sub-electrode layer overlaps the first connection pattern is greater than a size of an area where the first sub-electrode layer overlaps the first connection pattern, and
in the plan view, a size of an area where the second sub-electrode layer overlaps the second connection pattern is greater than a size of an area where the first sub-electrode layer overlaps the second connection pattern.

14. The display device of claim 1, wherein the separator includes a groove in which a portion of an upper surface of the separator is recessed.

15. The display device of claim 14, further comprising:
a dummy layer disposed in the groove, the dummy layer and the electrode layer including a same material, wherein
the electrode layer extends along a side surface of the separator to the upper surface of the separator, and
the electrode layer and the dummy layer are separated from each other by the groove.

16. The display device of claim 1, further comprising:
an intermediate layer disposed between the first electrode and the electrode layer and including an emission material.

17. A display device comprising:
a pixel driving circuit including a transistor;
a connection electrode electrically connected to the pixel driving circuit;
a first electrode disposed on the connection electrode;
a pixel defining layer covering at least a portion of the first electrode and defining an emission area;
a connection pattern electrically connected to the connection electrode and partially surrounding the emission area in a plan view;
a separator disposed on the pixel defining layer and the connection pattern and covering at least a portion of the connection pattern; and
a second electrode disposed on the first electrode and electrically connected to the connection pattern.

18. The display device of claim 17, wherein a cross-sectional shape of a portion of the separator is asymmetrical.

19. The display device of claim 18, wherein
a side surface of the portion of the separator contacts the connection pattern, and
another side surface, which is opposite to the side surface, of the portion of the separator contacts the pixel defining layer and does not contact the connection pattern.

20. The display device of claim 17, wherein
the separator defines an open area exposing a portion of the connection pattern in the plan view, and
the second electrode is disposed in the open area, contacts the connection pattern at a position adjacent to or overlapping the separator in the plan view, and is electrically connected to the pixel driving circuit through the connection electrode and the connection pattern.

21. The display device of claim 17, further comprising:
an intermediate layer disposed between the first electrode and the second electrode and including an emission material.

22. A display device comprising:
a pixel driving circuit including a transistor;
a connection electrode electrically connected to the pixel driving circuit;
an insulating layer defining a first sub-opening exposing at least a portion of the connection electrode in a plan view;
a first electrode disposed on the insulating layer;
a pixel defining layer covering at least a portion of the first electrode, defining an emission area, and defining a second sub-opening overlapping the first sub-opening in the plan view;
a connection pattern electrically connected to the connection electrode and surrounding the emission area in the plan view;
a separator disposed on the pixel defining layer and the connection pattern, covering at least a portion of the connection pattern, and overlapping the first sub-opening and the second sub-opening in the plan view; and
a second electrode disposed on the first electrode and electrically connected to the connection pattern.

23. The display device of claim 22, wherein
the connection pattern partially surrounds the emission area in the plan view, and
a cross-sectional shape of a portion of the separator is asymmetric.

24. The display device of claim 23, wherein
a side surface of the portion of the separator contacts the connection pattern, and
another side surface, which is opposite to the side surface, of the portion of the separator contacts the pixel defining layer and does not contact the connection pattern.

25. The display device of claim 22, wherein
the first sub-opening and the second sub-opening are connected to form an opening that penetrates the pixel defining layer and the insulating layer and exposes a portion of the connection electrode in the plan view, and
the opening overlaps the separator in the plan view.

26. The display device of claim 25, wherein the connection pattern is electrically connected to the connection electrode through the opening.

27. The display device of claim 22, wherein
the separator defines an open area exposing a portion of the connection pattern in the plan view, and
the second electrode is disposed in the open area, contacts the connection pattern at a position adjacent to or overlapping the separator in the plan view, and is electrically connected to the pixel driving circuit through the connection electrode and the connection pattern.

28. The display device of claim 22, further comprising:
an intermediate layer disposed between the first electrode and the second electrode and including an emission material.

29. An electronic device comprising:
a display device; and
a power supply configured to provide power to the display device,
wherein the display device comprises:
a first pixel driving circuit and a second pixel driving circuit each including a transistor;
a first connection electrode electrically connected to the first pixel driving circuit;
a second connection electrode electrically connected to the second pixel driving circuit;
a first electrode disposed on the first connection electrode and the second connection electrode;
a pixel defining layer covering at least a portion of the first electrode and defining a first emission area and a second emission area adjacent to each other;
a first connection pattern electrically connected to the first connection electrode and partially surrounding the first emission area in a plan view;
a second connection pattern electrically connected to the second connection electrode and partially surrounding the second emission area in the plan view;
a separator disposed on the pixel defining layer, the first connection pattern, and the second connection pattern and covering at least a portion of each of the first connection pattern and the second connection pattern; and
an electrode layer disposed on the first electrode and electrically connected to each of the first connection pattern and the second connection pattern.
